(19) United States
(12) Patent Application Publication
(10) Pub. No.: US 2020/0286923 A1
(43) Pub. Date: Sep. 10, 2020

(54) ARRAY ANTENNA, METHOD FOR PRODUCING SAME, AND LIQUID CRYSTAL ALIGNING AGENT FOR ARRAY ANTENNA

(71) Applicant: JSR CORPORATION, TOKYO (JP)

(72) Inventor: Kouji KASHISHITA, Tokyo (JP)

(73) Assignee: JSR CORPORATION, TOKYO (JP)

(21) Appl. No.: 16/880,995

(22) Filed: May 22, 2020

Related U.S. Application Data
(63) Continuation of application No. PCT/JP2018/041331, filed on Nov. 7, 2018.

(30) Foreign Application Priority Data
Dec. 27, 2017 (JP) 2017-252366

(51) Int. Cl. H01L 27/12; H01Q 21/06; H01L 23/66; H01Q 21/00; H01Q 13/10; H01Q 21/20

(52) U.S. Cl. CPC H01L 27/124; H01Q 21/065; H01L 23/66; H01L 2223/6677; H01Q 13/10; H01Q 21/20; H01Q 21/0012

(57) ABSTRACT

This array antenna 10 comprises a plurality of antenna units 11. This array antenna 10 is provided with a patch substrate 12, a slotted substrate 13 and a liquid crystal layer 14. At least one of the patch substrate 12 and the slotted substrate 13 is provided with a liquid crystal alignment film 22, 23 on the liquid crystal layer 14 side. The liquid crystal alignment film 22, 23 is formed using a polymer composition that contains a compound (M) which has at least one structure selected from the group consisting of partial structures represented by formula (1) and nitrogen-containing heterocyclic rings (in formula (1), R1 represents a hydrogen atom or a monovalent organic group having 1-10 carbon atoms; and each of R2 and R3 independently represents a divalent organic group, provided that the R2 and R3 moieties are not aromatic ring groups at the same time).

### CROSS-REFERENCE TO RELATED APPLICATION

This application is a Continuation of PCT International Application No. PCT/JP2018/041331 filed on Nov. 7, 2018, which claims priority under 35 U.S.C. § 119(a) to Japanese Patent Application No. 2017-252366 filed on Dec. 27, 2017. Each of the above applications is hereby expressly incorporated by reference, in its entirety, into the present application.

### TECHNICAL FIELD

The present disclosure relates to an array antenna, a method for producing the same, and a liquid crystal aligning agent for an array antenna.

### BACKGROUND ART

Dielectric antennas are small and lightweight, and thus are widely used as antennas to be mounted on televisions, mobile phones, personal computers, vehicles, and the like in various use applications (for example, for information communication, for telephones, for GPS, and the like). In addition, as dielectric antennas, focusing on the dielectric anisotropy of a liquid crystal material, various planar antennas having a dielectric layer formed of a liquid crystal material have been proposed in recent years (for example, refer to Patent Literature 1 and Patent Literature 2).

### CITATION LIST

### Patent Literature

### [Patent Literature 1]

PCT International Publication No. WO2016/141342

### [Patent Literature 2]

PCT International Publication No. WO2017/065255

### SUMMARY OF INVENTION

### Technical Problem

In dielectric antennas using a liquid crystal material, a dielectric layer is formed of a liquid crystal material having a large dielectric constant, thereby reducing a size of antennas. Meanwhile, in a case where a liquid crystal material having a large dielectric constant is used, dielectric loss increases, and there is a tendency for insufficient antenna performance being secured. In addition, a liquid crystal material which has a large dielectric constant and is used for dielectric antennas tends to be vulnerable to environmental stresses such as light, and there is a concern that the reliability of such antennas will not be sufficient.

The present disclosure provides an array antenna having low dielectric loss and excellent reliability.

### Solution to Problem

The present disclosure employs the following means.

[1] An array antenna that has a plurality of antenna units, the array antenna including: a first substrate having a first dielectric substrate, a plurality of patch electrodes formed on the first dielectric substrate, and a plurality of thin-film transistors formed on the first dielectric substrate; a second substrate having a second dielectric substrate disposed to face a surface of the first substrate on which the patch electrodes are formed, and a slot electrode formed on a surface of the second dielectric substrate facing the patch electrodes; a liquid crystal layer disposed between the first substrate and the second substrate; and a liquid crystal alignment film formed on a side of at least one of the first substrate and the second substrate and the side is near the liquid crystal layer, in which the liquid crystal alignment film is formed using a polymer composition that contains a compound [M] having at least one selected from the group consisting of a partial structure represented by Formula (1) and a nitrogen-containing heterocyclic ring.

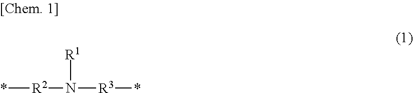

(In Formula (1), R¹ is a hydrogen atom or a monovalent organic group having 1 to 10 carbon atoms; R² and R³ are each independently a divalent organic group, where not both R² and R³ are aromatic ring groups; and “*” represents a bond.)

[2] An array antenna that has a plurality of antenna units, the array antenna including: a first substrate having a first dielectric substrate, a plurality of patch electrodes formed on the first dielectric substrate, and a plurality of thin-film transistors formed on the first dielectric substrate; a second substrate having a second dielectric substrate disposed to face a surface of the first substrate on which the patch electrodes are formed, and a slot electrode formed on a surface of the second dielectric substrate facing the patch electrodes; a liquid crystal layer disposed between the first substrate and the second substrate; and a liquid crystal alignment film formed on a side of at least one of the first substrate and the second substrate and the side is near the liquid crystal layer, in which the liquid crystal alignment film is formed using a polymer composition that contains a polymer having at least one partial structure selected from the group consisting of (V1) to (V5) in a side chain:

(V1) alkyl groups having 8 to 22 carbon atoms;

(V2) fluorine-containing alkyl groups having 6 to 18 carbon atoms;

(V3) monovalent groups in which any one of a benzene ring, a cyclohexane ring, and a heterocyclic ring is bonded to an alkyl group or fluorine-containing alkyl group having 1 to 20 carbon atoms;

(V4) monovalent groups which have a total of two or more rings of at least one kind selected from the group consisting of a benzene ring, a cyclohexane ring, and a heterocyclic ring, and in which the plurality of rings are bonded directly or via a divalent linking group; and

(V5) monovalent groups having a steroid skeleton and having 17 to 51 carbon atoms.

[3] An array antenna that has a plurality of antenna units, the array antenna including: a first substrate having a first dielectric substrate, a plurality of patch electrodes formed on the first dielectric substrate, and a plurality of thin-film transistors formed on the first dielectric substrate; a second substrate having a second dielectric substrate disposed to face a surface of the first substrate on which the patch electrodes are formed, and a slot electrode formed on a surface of the second dielectric substrate facing the patch electrodes; a liquid crystal layer disposed between the first substrate and the second substrate; and a liquid crystal alignment film formed on a side of at least one of the first substrate and the second substrate and the side is near the liquid crystal layer, in which the liquid crystal alignment film is formed using a polymer composition containing a compound having a crosslinkable group.
[4] An array antenna that has a plurality of antenna units, the array antenna including: a first substrate having a first dielectric substrate, a plurality of patch electrodes formed on the first dielectric substrate, and a plurality of thin-film transistors formed on the first dielectric substrate; a second substrate having a second dielectric substrate disposed to face a surface of the first substrate on which the patch electrodes are formed, and a slot electrode formed on a surface of the second dielectric substrate facing the patch electrodes; a liquid crystal layer disposed between the first substrate and the second substrate; and a liquid crystal alignment film formed on a side of at least one of the first substrate and the second substrate and the side is near the liquid crystal layer, in which the liquid crystal alignment film is formed using a polymer composition containing a polyimide.
[5] A liquid crystal aligning agent for an array antenna having a plurality of antenna units, in which the array antenna has a first substrate having a first dielectric substrate, a plurality of patch electrodes formed on the first dielectric substrate, and a plurality of thin-film transistors formed on the first dielectric substrate; a second substrate having a second dielectric substrate disposed to face a surface of the first substrate on which the patch electrodes are formed, and a slot electrode formed on a surface of the second dielectric substrate facing the patch electrodes; a liquid crystal layer disposed between the first substrate and the second substrate; and a liquid crystal alignment film formed on a side of at least one of the first substrate and the second substrate and the side is near the liquid crystal layer, the liquid crystal aligning agent for an array antenna including: at least one selected from the group consisting of (G1) to (G4):

(G1) compound having at least one selected from the group consisting of a partial structure represented by Formula (1) and a nitrogen-containing heterocyclic ring;

(G2) polymer having at least one partial structure selected from the group consisting of (V1) to (V5) in a side chain;

(G3) compound having a crosslinkable group; and

(G4) polyimide.

[6] A method for producing an array antenna having a plurality of antenna units, in which the array antenna has a first substrate having a first dielectric substrate, a plurality of patch electrodes formed on the first dielectric substrate, and a plurality of thin-film transistors formed on the first dielectric substrate; and a second substrate having a second dielectric substrate disposed to face a surface of the first substrate on which the patch electrodes are formed, and a slot electrode formed on a surface of the second dielectric substrate facing the patch electrodes, the method for producing an array antenna including: a step of form a liquid crystal alignment film on at least one surface of the first substrate and the second substrate on which electrodes are formed using the liquid crystal aligning agent for an array antenna according to [5]; and a step of allowing the first substrate and the second substrate to be disposed to face each other with a liquid crystal layer therebetween after forming the liquid crystal alignment film.

### Advantageous Effects of Invention

According to the above configurations, it is possible to obtain an array antenna having low dielectric loss and excellent reliability.

### BRIEF DESCRIPTION OF DRAWINGS

FIG. 1 is a plan view showing a schematic configuration of an array antenna.

FIG. 2 is a cross-sectional view showing a schematic configuration of a part of the array antenna.

### DESCRIPTION OF EMBODIMENTS

Hereinafter, embodiments of an array antenna will be described with reference to the drawings. In the following embodiments, the same or equivalent parts are denoted by the same reference numerals in the drawings, and the same description is adopted for parts with the same reference numerals.

(Configuration of Array Antenna)

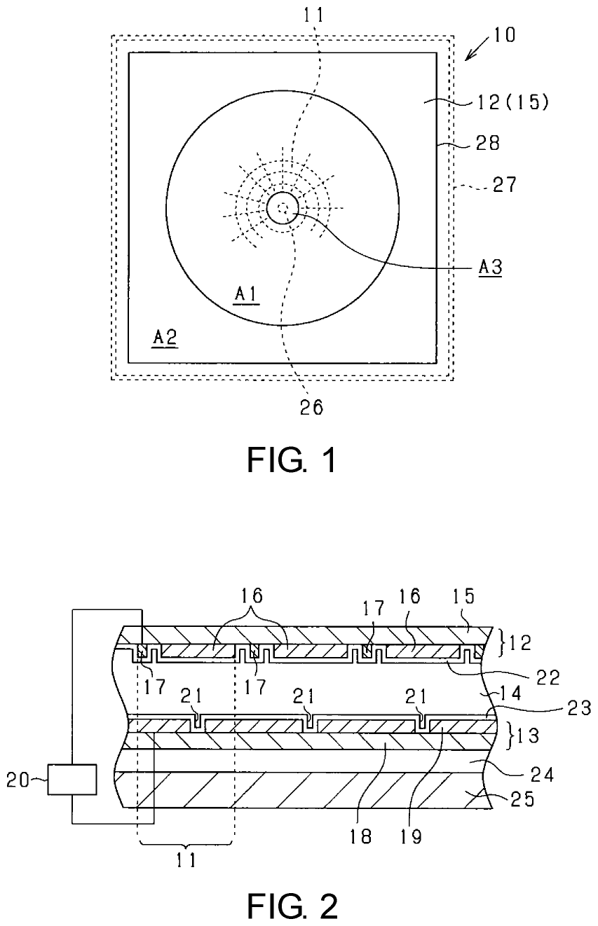

FIGS. 1 and 2 show an example of an array antenna 10 of the present embodiment. The array antenna 10 is a planar liquid crystal antenna utilizing a phenomenon that a dielectric constant of a liquid crystal material changes according to the strength of an electric field, and is a phased array antenna having a plurality of antenna units 11. The array antenna 10 controls an electric field applied to a liquid crystal material to change a dielectric constant of the liquid crystal material of each of the antenna units 11, thereby transmitting energy with radio frequency waves as electromagnetic waves in any direction in space or receiving electromagnetic waves in any direction in space.

The array antenna 10 is a radial line slot antenna in which the plurality of antenna units 11 are concentrically arranged in a wave transmission and reception region A1 functioning as a wave transmission and reception part, and can transmit or receive circularly polarized waves. As shown in FIG. 2, the array antenna 10 includes a patch substrate 12, a slotted substrate 13, and a liquid crystal layer 14. In the array antenna 10, the wave transmission and reception region A1 is annular, a wave non-transmission and non-reception region A2 is disposed outside the wave transmission and reception region A1, and a wave non-transmission and non-reception region A3 is disposed inside the wave transmission and reception region A1.

The patch substrate 12 has a dielectric substrate (first dielectric substrate) 15 such as a glass substrate or a plastic substrate, a plurality of patch electrodes 16 formed on one surface of the dielectric substrate 15, and a plurality of TFTs 17 respectively connected to each of the plurality of patch electrodes 16. Each of the patch electrodes 16 is a metal layer made of copper, aluminum, or the like, and has a thickness of, for example, about 1 to 2 μm. The TFTs 17 are respectively electrically connected to a gate bus line and a source bus line (which are not shown), and energization thereof is controlled by a control unit 20. The antenna units 11 are respectively configured by having one patch electrode 16 and one TFT 17. Each region of the antenna units 11 is defined by a gate bus line and a source bus line.

The slotted substrate 13 has a dielectric substrate (second dielectric substrate) 18 such as a glass substrate or a plastic substrate, and a slot electrode 19 on which a plurality of slots 21 are disposed. The slot electrode 19 is a metal layer made of copper, aluminum, or the like, and has a thickness of, for example, about 2 to 20 μm. Energization of the slot electrode 19 is controlled by the control unit 20. The plurality of slots 21 are formed on the slot electrode 19 by means that a pair of the slots extending in directions crossing each other are concentrically arranged in the wave transmission and reception region A1.

A first alignment film 22 is formed on a surface of the patch substrate 12 on which the electrodes are formed, and a second alignment film 23 is formed on a surface of the slotted substrate 13 on which the electrode is formed. The first alignment film 22 and the second alignment film 23 are liquid crystal alignment films controlling alignment of liquid crystal molecules, and are formed using a polymer composition containing a polymer component.

The patch substrate 12 and the slotted substrate 13 are disposed with a predetermined distance therebetween by a sealant disposed in the wave non-transmission and non-reception regions A2 and A3 such that the surfaces on which the electrodes are formed (that is, the surfaces on which the liquid crystal alignment films are formed) face each other. In each of the antenna units 11, the patch electrodes 16 are disposed to face the slots 21 (refer to FIG. 2). The liquid crystal layer 14 is provided adjacent to the first alignment film 22 and the second alignment film 23 in a space surrounded by the patch substrate 12, the slotted substrate 13, and the sealant. The liquid crystal layer 14 is filled with a liquid crystal material.

The liquid crystal material forming the liquid crystal layer 14 is preferably a material having a large dielectric anisotropy with respect to radio frequency waves such as microwaves or a millimeter waves, and having low dielectric loss (that is, tan δ). Specifically, for example, it is possible to use bistolane-based compounds (for example, a compound represented by Formula (R-1)), oligophenylene-based compounds (for example, a compound represented by Formula (R-2)), a mixture of a bistolane-based compound and an oligophenylene-based compound, and the like. A thickness of the liquid crystal layer 14 is, for example, 5 to 400 μm.

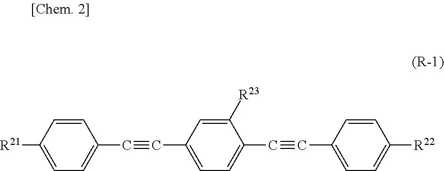

(In Formula (R-1), R²¹ to R²³ each independently represent an alkyl group, an alkoxy group, an alkenyl group, an alkenyloxy group, an alkoxyalkyl group, a cycloalkyl group, an alkylcycloalkyl group, a cycloalkenyl group, an alkylcycloalkenyl group, an alkylcycloalkylalkyl group, or an alkylcycloalkenylalkyl group which has 1 to 15 carbon atoms.)

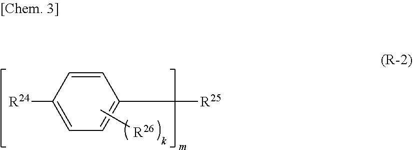

(In Formula (R-2), R²⁴ and R²⁵ each independently represent a hydrogen atom, a halogen atom, or an alkyl group, a fluorinated alkyl group, an alkoxy group, a fluorinated alkoxy group, an alkenyl group, a fluorinated alkenyl group, an alkenyloxy group, an alkoxyalkyl group, a fluorinated alkoxyalkyl group, a cycloalkyl group, an alkylcycloalkyl group, a cycloalkenyl group, an alkylcycloalkenyl group, an alkylcycloalkylalkyl group, or an alkylcycloalkenylalkyl group which has 1 to 15 carbon atoms; R²⁶ is a fluorine atom, a chlorine atom, or an alkyl group having 1 to 15 carbon atoms; k is an integer of 0 to 4; and m is an integer of 6 to 25.)

Specific examples of bistolane-based compounds as a liquid crystal material include compounds respectively represented by Formulas (r-1-1) to (r-1-4), and specific examples of oligophenylene-based compounds as a liquid crystal material include compounds respectively represented by Formulas (r-2-1) and (r-2-2). As the liquid crystal material, one kind can be used alone, or two or more kinds thereof can be used in combination.

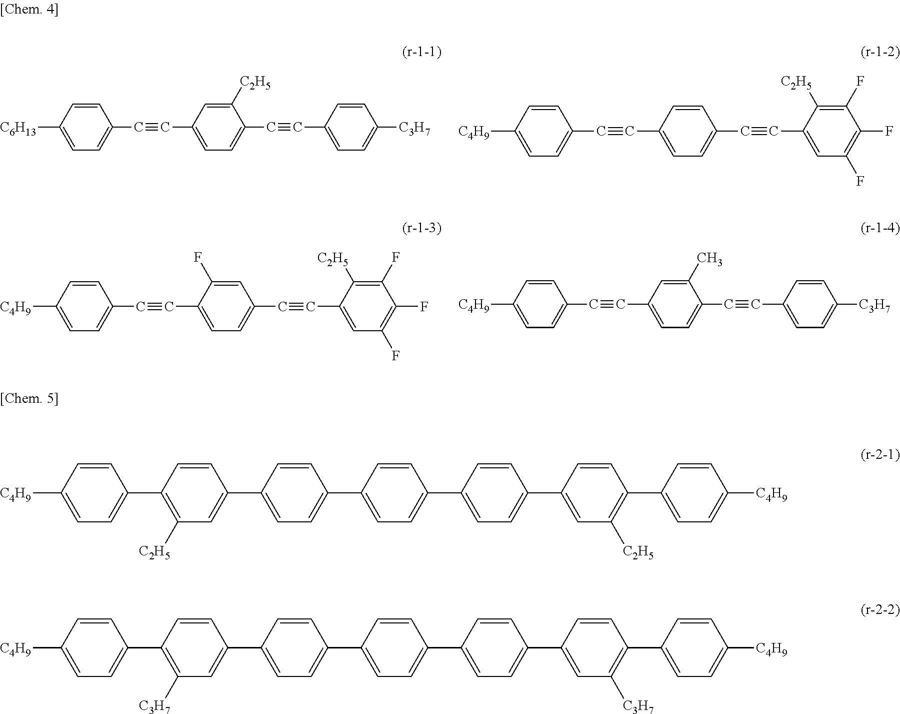

A ground plate 25 is disposed on a side opposite to the surface of the slotted substrate 13 on which the electrode is formed with a low dielectric layer 24 therebetween. The ground plate 25 is formed of an aluminum plate or a copper plate, and has a thickness of about several mm. The low dielectric layer 24 is a layer having a small dielectric constant with respect to radio frequency waves, and is an air layer in the present embodiment. Instead of the air layer, a resin layer made of a fluorine resin such as PTFE may be disposed as the low dielectric layer 24.

A power feed pin 26 is attached to the wave non-transmission and non-reception region A3 on the side opposite to the surface of the slotted substrate 13 on which the electrode is formed. The power feed pin 26 passes through the ground plate 25 and is connected to a signal line (not shown). The plurality of antenna units 11 are concentrically arranged around the power feed pin 26 in the wave transmission and reception region A1. The array antenna 10 receives electromagnetic waves of the space from the patch substrate 12 side or radiates electromagnetic waves to the space, and the slot electrode 19, the dielectric substrate 18, the low dielectric layer 24, and the ground plate 25 function as a waveguide to transmit energy from radio frequency waves.

In the array antenna 10, an internal unit 28 having the patch substrate 12, the slotted substrate 13, and the liquid crystal layer 14 is accommodated in a housing 27 made of resin (refer to FIG. 1). From the viewpoint that dielectric loss of the array antenna 10 can be lowered, the housing 27 is preferably a container made of resin which is formed using at least one selected from the group consisting of an epoxy resin, a polyimide resin, a liquid crystal polymer, and a fluorine resin, and the housing is formed using a fluorine resin (PTFE or the like) in the present embodiment. A size of the array antenna 10 is appropriately set according to communication traffic and the like, and is, for example, 20 cm to 3 m.

The array antenna 10 can be used for transmitting, receiving, or transmitting and receiving radio frequency waves such as microwaves and millimeter waves. Use applications thereof are not particularly limited, and for example, the array antenna can be preferably applied to antennas mounted on moving objects such as cars, railway vehicles, aircraft, ships, and robots, and specifically to antennas for information communication, antennas for broadcasting, antennas for telephones, antennas for GPS, and the like.

(Liquid Crystal Aligning Agent for Array Antenna)

Next, a liquid crystal aligning agent for an array antenna (hereinafter, also simply referred to as a “liquid crystal aligning agent”) which is used for forming the liquid crystal alignment films (the first alignment film 22 and the second alignment film 23) will be described. The liquid crystal aligning agent of the present disclosure is a liquid composition in which a polymer component is dissolved in, preferably a solvent, and contains at least one component selected from the group consisting of (G1) to (G4) shown below:

(G1) compound [M] having a specific partial structure containing a nitrogen atom;

(G2) polymer having a vertically alignable group;

(G3) compound having a crosslinkable group; and

(G4) polyimide.

The respective components will be described in detail below. In a case where the liquid crystal aligning agent contains a polyimide as a polymer component, at least one of the compound [M] and the polymer having a vertically alignable group may be a polyimide, or a polyimide may be incorporated as a component different from the compound [M] and the polymer having a vertically alignable group. In addition, the compound [M] may be a polymer having a vertically alignable group.

<Compound [M]>

The compound [M] is a compound having at least one selected from the group consisting of a partial structure represented by Formula (1) and a nitrogen-containing heterocyclic ring.

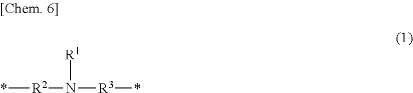

(In Formula (1), R¹ is a hydrogen atom or a monovalent organic group having 1 to 10 carbon atoms; R² and R³ are each independently a divalent organic group, where not both R² and R³ are aromatic ring groups; and “*” represents a bond.)

In Formula (1), examples of the monovalent organic group having 1 to 10 carbon atoms for R¹ include a monovalent hydrocarbon group having 1 to 10 carbon atoms, a protecting group, and the like. In the present specification, the “hydrocarbon group” includes a chain hydrocarbon group, an alicyclic hydrocarbon group, and an aromatic hydrocarbon group. The “chain hydrocarbon group” refers to a linear hydrocarbon group and a branched hydrocarbon group which are composed of only a chain structure and do not contain a cyclic structure in a main chain, but it may be saturated or unsaturated. The “alicyclic hydrocarbon group” includes a hydrocarbon group containing only an alicyclic hydrocarbon structure as a ring structure and not containing an aromatic ring structure, but it is not necessarily composed of only an alicyclic hydrocarbon structure and may include a group partially having a chain structure. The “aromatic hydrocarbon group” refers to a hydrocarbon group containing an aromatic ring structure as a ring structure, but it is not necessarily composed of only an aromatic ring structure, and a part thereof may have a chain structure or an alicyclic hydrocarbon structure.

Specific examples of cases in which R¹ is a monovalent organic group include alkyl groups such as a methyl group, an ethyl group, a propyl group, a butyl group, and a pentyl group; cycloalkyl groups such as a cyclopentyl group, a cyclohexyl group, and a cyclooctyl group; aryl groups such as a phenyl group and a methylphenyl group; aralkyl groups such as a benzyl group and a phenethyl group; protecting groups such as a t-butoxycarbonyl group, a benzyloxycarbonyl group, and a 9-fluorenylmethyloxycarbonyl group; and the like. R¹ is preferably a hydrogen atom, or an alkyl group or tert-butoxycarbonyl group which has 1 to 3 carbon atoms.

Examples of divalent organic groups represented by R² and R³ include divalent hydrocarbon groups; divalent groups in which a methylene group of a divalent hydrocarbon group is substituted by —O—, —CO—, —COO—, —NR⁷—, or —CO—NR⁷— (where R⁷ is a hydrogen atom, a monovalent hydrocarbon group or protecting group which has 1 to 10 carbon atoms, the same applies hereinafter); divalent heterocyclic groups; and the like. However, not both R² and R³ are aromatic ring groups. In the present specification, the “aromatic ring group” refers to an m-valent group in which m hydrogen atoms have been removed from a ring portion of an aromatic ring. The “aromatic ring” is a ring belonging to aromatic groups and includes a benzene ring, a condensed benzene ring, and a heteroaromatic ring. The “heterocyclic group” refers to a p-valent group in which p hydrogen atoms have been removed from a ring portion of a heterocyclic ring.

It is preferable that at least one of R² and R³ do not have a carbon-carbon unsaturated bond, it is more preferable that both R² and R³ do not have a carbon-carbon unsaturated bond, and it is even more preferable that R² and R³ have a chain structure not having a carbon-carbon unsaturated bond, from the viewpoint that then, charge leakage can be reduced, thereby reducing change in dielectric constant, and dielectric loss of an array antenna can be further lowered. Preferable examples of R² and R³ include an alkanediyl group having 1 to 20 carbon atoms, or a group in which a methylene group of an alkanediyl group is substituted by —O—, —CO—, —COO—, —NR⁷—, or —CO—NR⁷—. The number of carbon atoms in R² and R³ is preferably 2 or more and more preferably 2 to 20.

The partial structure represented by Formula (1) is preferably a partial structure represented by Formula (1-1) among the above formulas, from the viewpoint of sufficiently obtaining an effect of lowering dielectric loss.

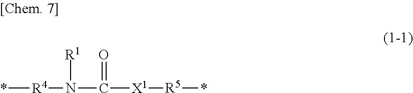

(In Formula (1-1), R¹ is a hydrogen atom or a monovalent organic group having 1 to 10 carbon atoms; X¹ is a single bond, an oxygen atom, or —NR⁶— (where R⁶ is a hydrogen atom or a monovalent organic group having 1 to 10 carbon atoms); R⁴ and R⁵ are each independently a divalent saturated hydrocarbon group; and “*” represents a bond.)

The description of R¹ in Formula (1) applies to R¹ and R⁶ in Formula (1-1). R⁶ is preferably a hydrogen atom, or an alkyl group or tert-butoxycarbonyl group which has 1 to 3 carbon atoms. The divalent saturated hydrocarbon group for R⁴ and R⁵ is preferably an alkanediyl group having 1 to 20 carbon atoms or a cycloalkanediyl group having 5 to 20 carbon atoms, and more preferably an alkanediyl group having 1 to 10 carbon atoms.

X¹ is preferably —NR⁶— and is more preferably —NH—, —NCH₃—, —NC₂H₅—, —NC₃H₇—, or —NX²— (where X² is a tert-butoxycarbonyl group) from the viewpoint that then, charge leakage can be further reduced, thereby further lowering dielectric loss, and reliability of the array antenna 10 can be further increased.

In a case where the compound [M] has a nitrogen-containing heterocyclic ring, the nitrogen-containing heterocyclic ring is not particularly limited as long as a nitrogen atom is present in the ring. The ring is preferably at least one selected from the group consisting of piperidine, piperazine, hexamethyleneimine, azole, pyridine, azepine, pyrrole, imidazole, pyrazole, oxazole, thiazole, imidazoline, pyrazine, pyrimidine, pyridazine, morpholine, thiazine, indole, isoindole, benzimidazole, purine, quinoline, isoquinoline, quinoxaline, cinnoline, pteridine, acridine, carbazole, and benzo-C-cinnoline. The ring is more preferably at least one selected from the group consisting of piperidine, piperazine, hexamethyleneimine, pyridine, pyrrole, imidazole, pyrazole, pyrazine, pyrimidine, and pyridazine.

The compound [M] may be a polymer component, or may be an additive component mixed in separately from a polymer component.

In a case where the compound [M] is an additive component, the compound [M] is preferably a compound having a nitrogen-containing heterocyclic ring as at least one structure (hereinafter referred to as a “specific partial structure”) selected from the group consisting of the partial structure represented by Formula (1) and a nitrogen-containing heterocyclic ring. The nitrogen-containing heterocyclic ring included in the compound [M] as an additive component is preferably a ring showing aromaticity, that is, a nitrogen-containing heteroaromatic ring. The nitrogen-containing heteroaromatic ring is preferably a pyrrole ring, an imidazole ring, a pyrazole ring, a triazole ring, a pyridine ring, a pyrimidine ring, a pyridazine ring, or a pyrazine ring. These nitrogen-containing heteroaromatic rings may be rings in which a substituent has been introduced at a carbon atom constituting the ring. Examples of substituents include a halogen atom, an alkyl group, an alkoxy group, and the like.

Preferable specific examples of the compound [M] as an additive component include an amine compound [C] represented by Formula (c-1), and the like.

[Chem. 8]

H₂N-A¹¹-A¹² (c-1)

(In Formula (c-1), A¹¹ is a divalent organic group having a chain hydrocarbon group or an alicyclic hydrocarbon group; and A¹² is a nitrogen-containing aromatic heterocyclic ring, where a primary amino group in the formula is bonded to a chain hydrocarbon group or an alicyclic hydrocarbon group included in A¹¹.)

In Formula (c-1), examples of divalent organic groups for A¹¹ include a divalent chain hydrocarbon group, a divalent alicyclic hydrocarbon group, —O—R²⁷—, —CO—R²⁷— (where R²⁷ is a divalent chain hydrocarbon group or alicyclic hydrocarbon group), and the like. In addition, the divalent organic group for A¹¹ may be a divalent group having aromatic hydrocarbon groups such as —O—, —NH—, —CO—O—, —CO—NH—, —CO—, —S—, —S(O)₂—, —Si(CH₃)₂—, —O—Si(CH₃)₂—, —O—Si(CH₃)₂—O—, and a phenylene group, heterocyclic groups such as a pyridinylene group, and the like between a carbon-carbon bond in a divalent chain hydrocarbon group or a divalent alicyclic hydrocarbon group; a divalent group in which at least one hydrogen atom in a divalent chain hydrocarbon group or a divalent alicyclic hydrocarbon group is substituted by a halogen atom such as a fluorine atom, a chlorine atom, a bromine atom, and an iodine atom, an aromatic hydrocarbon group such as a phenyl group, a hydroxyl group, a halogenated alkyl group, and the like; and the like.

Among the above examples, A¹¹ is preferably a divalent organic group having a chain hydrocarbon group, and is more preferably a divalent chain hydrocarbon group. The number of carbon atoms in A¹¹ is preferably 1 to 20, more preferably 1 to 15, and even more preferably 1 to 10. The above description applies to the nitrogen-containing heteroaromatic ring for A¹².

Specific examples of the amine compound [C] include compounds respectively represented by Formulas (c-1-1) to (c-1-32). As the amine compound [C], one kind thereof may be used alone or two or more kinds thereof may be used in combination.

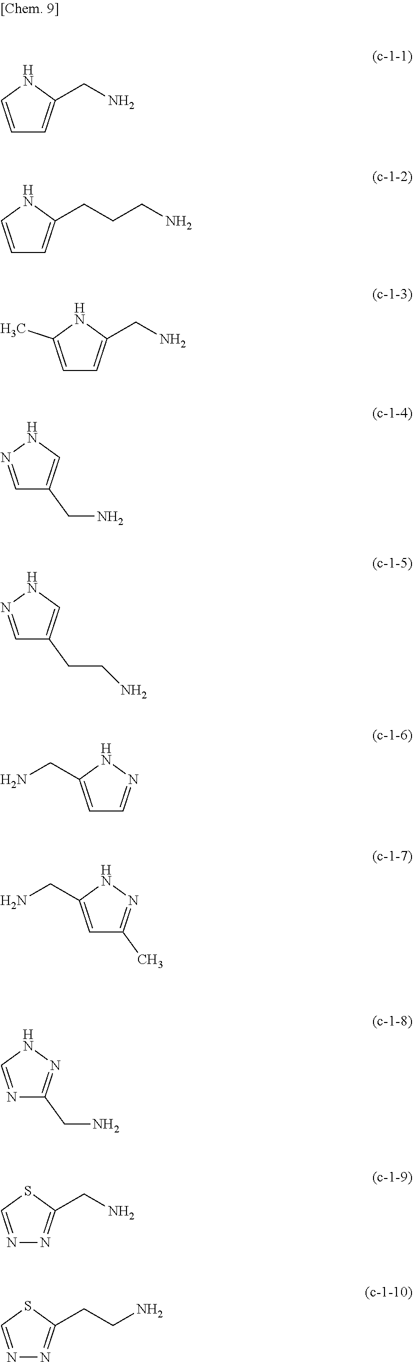

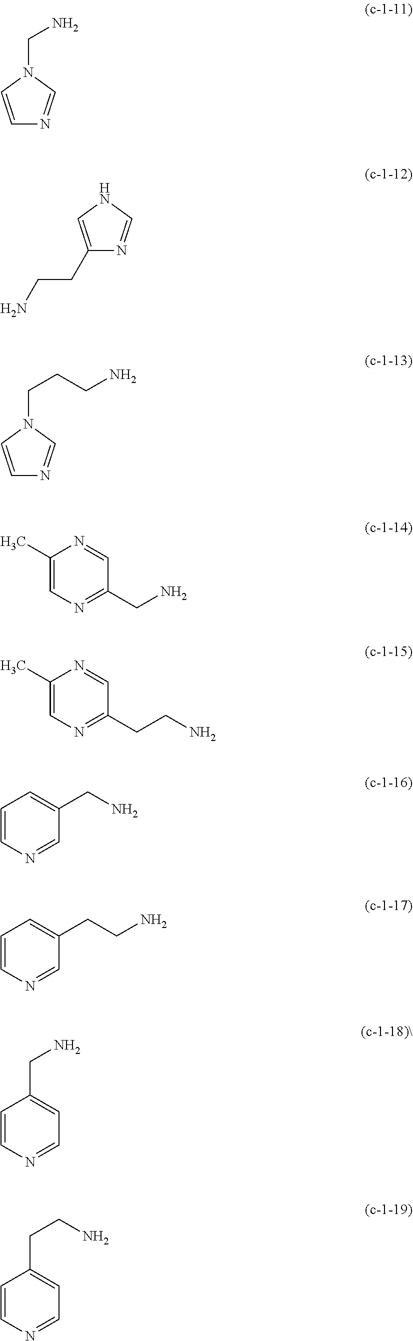

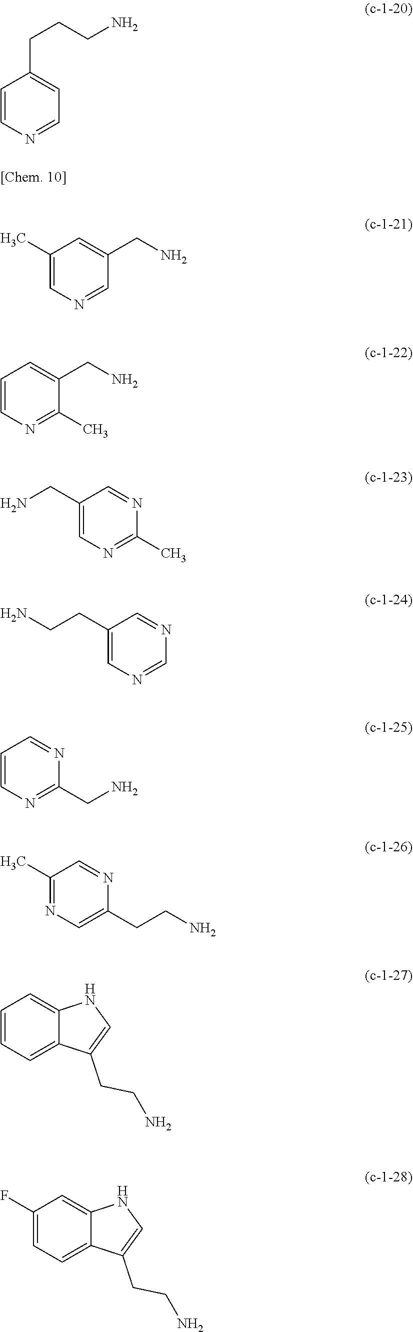

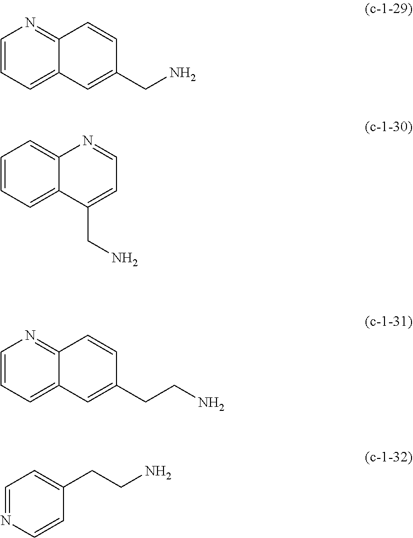 [SMILES: NCc1ccc2ncccc2c1 ; NCc1ccnc2ccccc12 ; NCCc1ccc2ncccc2c1 ; NCCc1ccncc1]

In a case where the compound [M] is a polymer, it is preferable that a specific partial structure constitute a part of a main chain in the polymer. In the present specification, the “main chain” refers to a “trunk” portion composed of the longest chain of atoms in a polymer. It is permissible for this “trunk” portion to have a ring structure. However, there may be a case in which a specific partial structure is present also in a portion other than a main chain, for example, in a side chain (a portion branching from a “trunk” of a polymer). In a case where the compound [M] is a polymer, a main skeleton of the polymer is not particularly limited, and examples thereof include main skeletons such as a polyamic acid, a polyamic acid ester, a polyimide, a polyorganosiloxane, a polyester, cellulose derivatives, a polyacetal, polystyrene derivatives, poly(styrene-phenylmaleimide) derivatives, and poly(meth)acrylates.

In a case where the compound [M] is a polymer, the compound [M] is preferably at least one polymer (hereinafter referred to as a polymer [P]) selected from the group consisting of a polyamic acid, a polyamic acid ester, and a polyimide from the viewpoint that then, a high alignment performance is exhibited even in a case where the above-described liquid crystal material having a large dielectric constant is used. The polymer [P] is more preferably a polyimide from the viewpoint that then, charge leakage can be reduced, and thereby further reducing change in dielectric constant.

A method for synthesizing the polymer [P] is not particularly limited. For example, in a case where the polymer [P] is a polyamic acid, the polyamic acid (hereinafter referred to as a “polyamic acid [P])” can be obtained by reacting a tetracarboxylic dianhydride with a diamine.

Examples of tetracarboxylic dianhydrides used in the synthesis of the polyamic acid [P] include aliphatic tetracarboxylic dianhydrides, alicyclic tetracarboxylic dianhydrides, aromatic tetracarboxylic dianhydrides, and the like. Specific examples of aliphatic tetracarboxylic dianhydrides include 1,2,3,4-butanetetracarboxylic dianhydride, ethylenediaminetetraacetic acid dianhydride, and the like.

Examples of alicyclic tetracarboxylic dianhydrides include 1,2,3,4-cyclobutanetetracarboxylic dianhydride; 1,3-dimethyl-1,2,3,4-cyclobutanetetracarboxylic dianhydride; 2,3,5-tricarboxycyclopentylacetic acid dianhydride; 1,3,3a,4,5,9b-hexahydro-5-(tetrahydro-2,5-dioxo-3-furanyl)-naphtho[1,2-c]furan-1,3-dione; 1,3,3a,4,5,9b-hexahydro-8-methyl-5-(tetrahydro-2,5-dioxo-3-furanyl)-naphtho[1,2-c]furan-1,3-dione; 3-oxabicyclo[3.2.1]octane-2,4-dione-6-spiro-3′-(tetrahydrofuran-2′,5′-dione); 5-(2,5-dioxotetrahydro-3-furanyl)-3-methyl-3-cyclohexene-1,2-dicarboxylic anhydride; 2,4,6,8-tetracarboxybicyclo[3.3.0]octane-2:4,6:8-dianhydride; cyclohexanetetracarboxylic dianhydride; cyclopentanetetracarboxylic dianhydride; and the like.

Examples of aromatic tetracarboxylic dianhydrides include pyromellitic dianhydride; 4,4′-(hexafluoroisopropylidene) diphthalic anhydride; p-phenylenebis(trimellitic acid monoester anhydride); ethylene glycol bis(anhydrotrimellitate); 1,3-propylene glycol bis(anhydrotrimellitate); and the like. In addition to these examples, it is also possible to use a tetracarboxylic dianhydride disclosed in Japanese Patent Laid-Open No. 2010-97188. As the tetracarboxylic dianhydride, one kind can be used alone, or two or more kinds thereof can be used in combination.

An alicyclic tetracarboxylic dianhydride is preferably contained as the tetracarboxylic dianhydride used in the synthesis from the viewpoint that then, solubility of a polymer to be obtained in a solvent can be further increased, and charge leakage can be reduced, thereby lowering dielectric loss. A proportion of the alicyclic tetracarboxylic dianhydride used is preferably 10 mol % or more and more preferably 30 mol % or more with respect to a total amount of the tetracarboxylic dianhydride used in the synthesis of a polyamic acid. The upper limit value of the proportion of the alicyclic tetracarboxylic dianhydride used can be set by selecting within a range of 100 mol % or less.

It is possible to obtain a polyamic acid that is the compound [M] partially using a diamine having a specific partial structure (hereinafter referred to as a “specific diamine”) as a diamine used in the synthesis of the polyamic acid [P]. The specific diamine is preferably a compound represented by Formula (4).

H₂N-B¹-A²-B²-NH₂ (4)

(In Formula (4), A² is a divalent group having the partial structure represented by Formula (1) or a nitrogen-containing heterocyclic ring; and B¹ and B² are each independently a phenylene group, a pyridinediyl group, or a pyrimidinediyl group.)

In Formula (4), in a case where A² is a divalent group having the partial structure represented by Formula (1), A² preferably has the partial structure represented by Formula (1-1).

In a case where A² is a divalent group having a nitrogen-containing heterocyclic ring, it is preferable that A² have a partial structure represented by Formula (2) as a nitrogen-containing heterocyclic structure, and it is more preferable that the partial structure represented by Formula (2) be bonded to at least one of B¹ and B² from the viewpoint that then, charge leakage is reduced, and thereby an effect of lowering dielectric loss of the array antenna 10 becomes high.

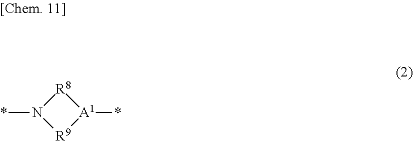

(In Formula (2), A¹ is a nitrogen atom or —CH—, and R⁸ and R⁹ are each independently an alkanediyl group having 1 to 4 carbon atoms.)

Specific examples of specific diamines as compounds in which A² is a divalent group having the partial structure represented by Formula (1) include compounds respectively represented by Formulas (N-1-1) to (N-1-7), and the like. Specific examples of specific diamines as compounds in which A² is a divalent group having a nitrogen-containing heterocyclic ring include 1,4-bis-(4-aminophenyl)-piperazine, compounds respectively represented by Formulas (N-2-1) to (N-2-6), and the like. As the specific diamine, one kind may be used alone, or two or more kinds thereof may be used in combination.

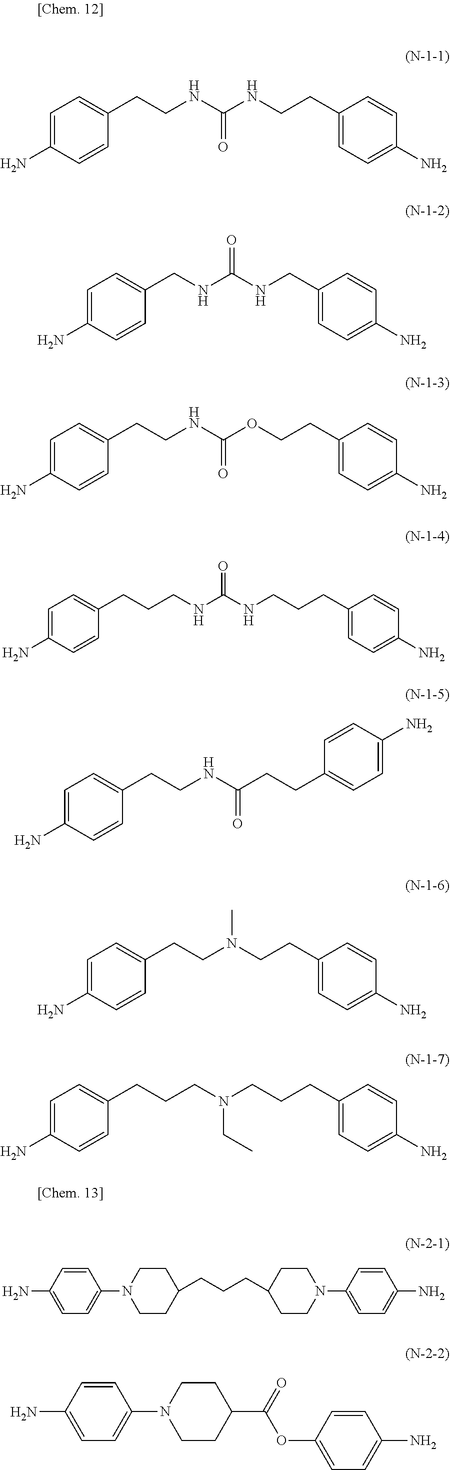

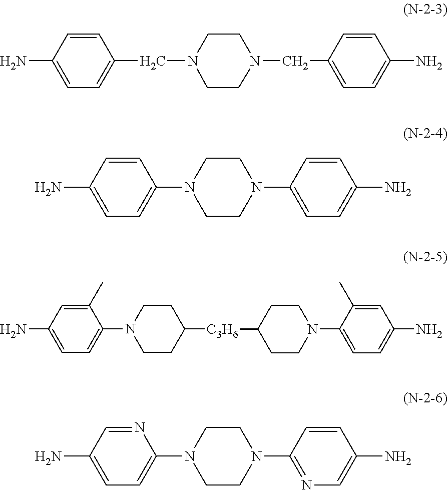

In synthesizing the polyamic acid [P], a diamine compound not having a specific partial structure (hereinafter referred to as the “other diamine”) may be used together with the specific diamine. Specific examples of other diamines are as follows: aliphatic diamines such as metaxylylenediamine, 1,3-propanediamine, tetramethylenediamine, pentamethylenediamine, and hexamethylenediamine; alicyclic diamines such as 1,4-diaminocyclohexane, and 4,4′-methylenebis(cyclohexylamine);

aromatic diamines such as dodecanoloxydiaminobenzene, hexadecanoloxydiaminobenzene, octadecanoxydiaminobenzene, cholestanyloxydiaminobenzene, cholesteryloxydiaminobenzene, cholestanyl diaminobenzoate, cholesteryl diaminobenzoate, lanostanyl diaminobenzoate, 3,6-bis(4-aminobenzoyloxy)cholestane, 3,6-bis(4-aminophenoxy)cholestane, and 1,1-bis(4-((aminophenyl)methyl)phenyl)-4-butylcyclohexane; side chain type diamines such as a compound represented by Formula (E-1):

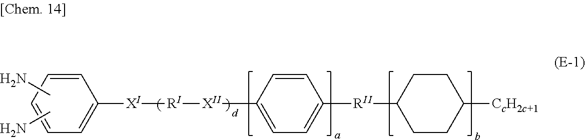

(in Formula (E-1), X^{I} and X^{II} are each independently a single bond, —O—, —COO—, or —OCO—; R¹ is an alkanediyl group having 1 to 3 carbon atoms; R^{II} is a single bond or an alkanediyl group having 1 to 3 carbon atoms; a is 0 or 1; b is an integer of 0 to 2; c is an integer of 1 to 20; and d is 0 or 1, where not both a and b are 0.);

non-side chain type diamines such as p-phenylenediamine, 4,4′-diaminodiphenylmethane, 4-aminophenyl-4′-aminobenzoate, 4,4′-diaminoazobenzene, 3,5-diaminobenzoic acid, 1,5-bis(4-aminophenoxy)pentane, bis[2-(4-aminophenyl)ethyl]hexanedioic acid, 2,2′-dimethyl-4,4′-diaminobiphenyl, 2,2′-bis(trifluoromethyl)-4,4′-diaminobiphenyl, 4,4′-diaminodiphenyl ether, 2,2-bis[4-(4-aminophenoxy)phenyl]propane, 1,4-bis(4-aminophenoxy)benzene, and 4,4′-bis (4-aminophenoxy)biphenyl;

diamino organosiloxanes such as 1,3-bis(3-aminopropyl)-tetramethyldisiloxane; and the like. In addition to the above examples, diamines disclosed in Japanese Patent Laid-Open No. 2010-97188 can be used. As the other diamine, one kind thereof can be used alone, or two or more kinds thereof can be used in combination. It is possible to obtain a polymer having a specific partial structure and a vertically alignable group using a side chain type diamine as at least a part of the other diamine. In a case where the liquid crystal aligning agent contains the polymer having a specific partial structure and a vertically alignable group, the compound [M] is also a polymer having a vertically alignable group. A case in which the polymer further having a vertically alignable group is contained as the compound [M] in the liquid crystal aligning agent is preferable from the viewpoint that then, it is possible to sufficiently improve reliability of an antenna device for long-term operation.

In a case of synthesizing the polyamic acid [P], a proportion of the specific diamine used (a total amount in a case where two or more kinds are used) is preferably 10 mol % or more, more preferably 20 mol % or more, and even more preferably 30 mol % or more with respect to a total amount of diamine compounds used in the synthesis. In addition, the upper limit value of the proportion of the specific diamine used is preferably 90 mol % or less and more preferably 80 mol % or less with respect to a total amount of diamine compounds used for the synthesis.

As the other diamine, a diamine having the partial structure in Formula (1) in which both R² and R³ are aromatic ring groups may be used. A proportion thereof used is preferably 3 mol % or less, more preferably 1 mol % or less, and even more preferably 0.5 mol % or less with respect to a total amount of diamines used for the synthesis of the polyamic acid [P]. It is particularly preferable that the other diamine do not contain a diamine having the partial structure in Formula (1) in which both R² and R³ are aromatic ring groups.

The polyamic acid [P] can be obtained by reacting a tetracarboxylic dianhydride with a diamine which are described above, if necessary, together with a molecular weight modifier. A proportion of the tetracarboxylic dianhydride and the diamine used for the synthesis reaction of the polyamic acid is preferably a proportion such that an acid anhydride group of the tetracarboxylic dianhydride becomes 0.2 to 2 equivalents to 1 equivalent of an amino group of the diamine. Examples of molecular weight modifiers include acid monoanhydrides such as maleic acid anhydride, phthalic acid anhydride, and itaconic acid anhydride; monoamine compounds such as aniline, cyclohexylamine, and n-butylamine; monoisocyanate compounds such as phenyl isocyanate and naphthyl isocyanate; and the like. A proportion of the molecular weight modifier used is preferably 20 parts by mass or less with respect to a total of 100 parts by mass of the tetracarboxylic dianhydride and the diamine compound used.

The synthesis reaction of the polyamic acid [P] is preferably performed in an organic solvent. In this case, a reaction temperature is preferably −20° C. to 150° C., and a reaction time is preferably 0.1 to 24 hours. Examples of organic solvents used in the reaction include aprotic polar solvents, phenol solvents, alcohols, ketones, esters, ethers, halogenated hydrocarbons, hydrocarbons, and the like. As a particularly preferable organic solvent, at least one selected from the group consisting of N-methyl-2-pyrrolidone, N,N-dimethylacetamide, N,N-dimethylformamide, dimethyl sulfoxide, γ-butyrolactone, tetramethylurea, hexamethylphosphortriamide, m-cresol, xylenol, and halogenated phenol is used as the solvent. Alternatively, it is preferable to use a mixture of one or more kinds thereof and another organic solvent (for example, a poor solvent for polyamic acids such as butyl cellosolve and diethylene glycol diethyl ether). An amount (a) of the organic solvent used is preferably an amount such that a total amount (b) of the tetracarboxylic dianhydride and the diamine compound becomes 0.1% to 50% by mass with respect to a total amount (a+b) of a reaction solution. In this manner, a reaction solution obtained by dissolving the polyamic acid [P] is obtained. This reaction solution may be directly used for preparing a liquid crystal aligning agent, or may be used for preparing a liquid crystal aligning agent after isolating the polyamic acid [P] contained in the reaction solution.

In a case where the polymer [P] is a polyamic acid ester, the polyamic acid ester can be obtained by, for example, [I] method of reacting the polyamic acid [P] to be obtained by the above synthesis reaction with an esterifying agent, [II] method of reacting a tetracarboxylic diester with a diamine, [III] method of reacting a tetracarboxylic diester dihalide with a diamine, or the like. Examples of the esterifying agent of [I] include methanol, ethanol, a hydroxyl-group-containing compound having a cinnamic acid structure, and the like. The tetracarboxylic diester used in [II] can be obtained by ring-opening a tetracarboxylic dianhydride with alcohols or the like. The tetracarboxylic diester dihalide used in [III] can be obtained by reacting the tetracarboxylic diester obtained as described above with a suitable chlorinating agent such as thionyl chloride.

The obtained polyamic acid ester may have only an amic acid ester structure, or may be a partially esterified product having both an amic acid structure and an amic acid ester structure. The reaction solution obtained by dissolving the polyamic acid ester may be directly used for preparing a liquid crystal aligning agent, or may be used for preparing a liquid crystal aligning agent after isolating the polyamic acid ester contained in the reaction solution.

In a case where the polymer [P] is a polyimide, the polyimide can be obtained by, for example, dehydrating and ring-closing the polyamic acid [P] synthesized as described above for imidization. The polyimide may be a completely imidized product obtained by dehydrating and ring-closing all amic acid structures of the polyamic acid [P] that is a precursor of the polyimide, or may be a partially imidized product in which only a part of an amic acid structure is dehydrated and ring-closed, and both the amic acid structure and an imide ring structure are present. An imidization ratio of the polyimide is preferably 20% to 99% and is more preferably 30% to 90%. This imidization ratio is obtained by representing a ratio of the number of imide ring structures to a total of the number of amic acid structures and the number of imide ring structures of the polyimide by a percentage. A part of an imide ring may be an isoimide ring.

The dehydration and ring-closure of the polyamic acid [P] is preferably carried out by a method of dissolving the polyamic acid [P] in an organic solvent, adding a dehydrating agent and a dehydration and ring-closure catalyst to the solution, and heating as necessary. In this method, as the dehydrating agent, it is possible to use, for example, acid anhydrides such as acetic acid anhydride, propionic acid anhydride, and trifluoroacetic acid anhydride. An amount of the dehydrating agent used is preferably 0.01 to 20 mol per 1 mol of the amic acid structure of the polyamic acid. As the dehydration and ring-closure catalyst, it is possible to use, for example, tertiary amines such as pyridine, collidine, lutidine, and triethylamine. An amount of the dehydration and ring-closure catalyst used is preferably 0.01 to 10 mol per 1 mol of the dehydrating agent used. Examples of organic solvents used include the organic solvents exemplified as organic solvents used in the synthesis of the polyamic acid [P]. A reaction temperature of the dehydration and ring-closure reaction is preferably 0° C. to 180° C., and a reaction time is preferably 1.0 to 120 hours. In this manner, a reaction solution containing the polyimide is obtained. This reaction solution may be directly used for preparing a liquid crystal aligning agent, or may be used for preparing a liquid crystal aligning agent after isolating the polyimide.

Regarding a solution viscosity of the polymer [P], in a case where this polymer is used as a solution having a concentration of 10% by mass, a solution viscosity is preferably 10 to 800 mPa·s, and a solution viscosity is more preferably 15 to 500 mPa·s. The solution viscosity (mPa·s) is a value measured at 25° C. using an E-type rotational viscometer to a polymer solution which has a concentration of 10% by mass and prepared using a good solvent (such as γ-butyrolactone and N-methyl-2-pyrrolidone) for the polymer [P].

A weight-average molecular weight (Mw) of the polymer [P], which is measured by gel permeation chromatography (GPC), in terms of polystyrene is preferably 1,000 to 500,000, and more preferably 2,000 to 300,000. In addition, a molecular weight distribution (Mw/Mn) represented by a ratio of Mw to a number average molecular weight (Mn), which is measured by GPC, in terms of polystyrene is preferably 15 or less and more preferably 10 or less.

In a case where the compound [M] is a polymer, a content ratio of the compound [M] in the liquid crystal aligning agent is preferably 50 parts by mass or more, more preferably 60 parts by mass or more, and even more preferably 80 parts by mass or more with respect to a total of 100 parts by mass of solid components (components other than the solvent) in the liquid crystal aligning agent, from the viewpoint that then, an effect of lowering dielectric loss of the array antenna 10 can be sufficiently obtained. In addition, in a case where the compound [M] is an additive component, a content ratio thereof is preferably 0.5 parts by mass or more, more preferably 1 to 20 parts by mass, and even more preferably 2 to 15 parts by mass with respect to a total of 100 parts by mass of polymer components in the liquid crystal aligning agent.

<Polymer Having Vertically Alignable Group>

A polymer having a vertically alignable group (hereinafter referred to as a “polymer [Q]”) is a polymer having at least one kind of side chain structures (hereinafter referred to as a “vertically alignable group”) selected from the group consisting of (V1) to (V5) below:

(V1) alkyl groups having 8 to 22 carbon atoms;

(V2) fluorine-containing alkyl groups having 6 to 18 carbon atoms;

(V3) monovalent groups in which any one of a benzene ring, a cyclohexane ring, and a heterocyclic ring is bonded to an alkyl group or fluorine-containing alkyl group having 1 to 20 carbon atoms;

(V4) monovalent groups which have a total of two or more rings of at least one kind selected from the group consisting of a benzene ring, a cyclohexane ring, and a heterocyclic ring, and in which the plurality of rings are bonded directly or via a divalent linking group; and

(V5) monovalent groups having a steroid skeleton and having 17 to 51 carbon atoms.

A main chain of the polymer [Q] is not particularly limited, and examples thereof include a polyamic acid, a polyamic acid ester, a polyimide, a polyorganosiloxane, a poly(meth)acrylate, and the like. Among the above examples, the polymer [Q] is preferably at least one selected from the group consisting of a polyamic acid, a polyamic acid ester, and a polyimide. The polymer [Q] is particularly preferably a polyimide from the viewpoint that then, an effect of improving reliability of an antenna device for long-term operation becomes high. The liquid crystal aligning agent may contain a polymer having a vertically alignable group and a specific partial structure.

The vertically alignable group contained in a polymer component of the liquid crystal aligning agent is preferably at least one selected from the group consisting of (V4) and (V5) among (V1) to (V5) from the viewpoint that then, reliability of an antenna device can be further improved.

Specific examples of vertically alignable groups are as follows: alkyl groups of (V1) such as an n-octyl group, an n-nonyl group, an n-decyl group, an n-dodecyl group, an n-tridecyl group, an n-tetradecyl group, an n-heptadecyl group, and an n-octadecyl group; fluorine-containing alkyl groups of (V2) such as a group in which at least one hydrogen atom of the alkyl group of (V1) is substituted with a fluorine atom; groups of (V3) and groups of (V4) such as a group represented by Formula (6); and groups of (V5) such as a cholestanyl group, a cholesteryl group, and a lanostanyl group.

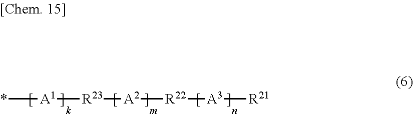

(In Formula (6), A¹ to A³ are each independently a phenylene group or a cyclohexylene group, and may have a substituent on a ring portion; R²¹ is a hydrogen atom, an alkyl group having 1 to 20 carbon atoms, an alkoxy group having 1 to 20 carbon atoms, an alkyl group having 1 to 20 carbon atoms in which at least one hydrogen atom is substituted by a fluorine atom, an alkoxy group having 1 to 20 carbon atoms in which at least one hydrogen atom is substituted by a fluorine atom, or a fluorine atom; R²² and R²³ are each independently a single bond, —O—, —COO—, —OCO—, or an alkanediyl group having 1 to 3 carbon atoms; k, m, and n are integers of 0 or greater satisfying 1≤k+m+n≤4, where k+m+n≥2 is satisfied in a case where R²¹ is a hydrogen atom, an alkyl group having 1 to 3 carbon atoms, or a fluorine atom; and “*” represents a bond.)

Specific examples of the group represented by Formula (6) include groups represented by the following formula. Examples of substituents that may be included on a ring portion of each of A¹ to A³ include a fluorine atom, an alkyl group having 1 to 3 carbon atoms, and an alkoxy group having 1 to 3 carbon atoms.

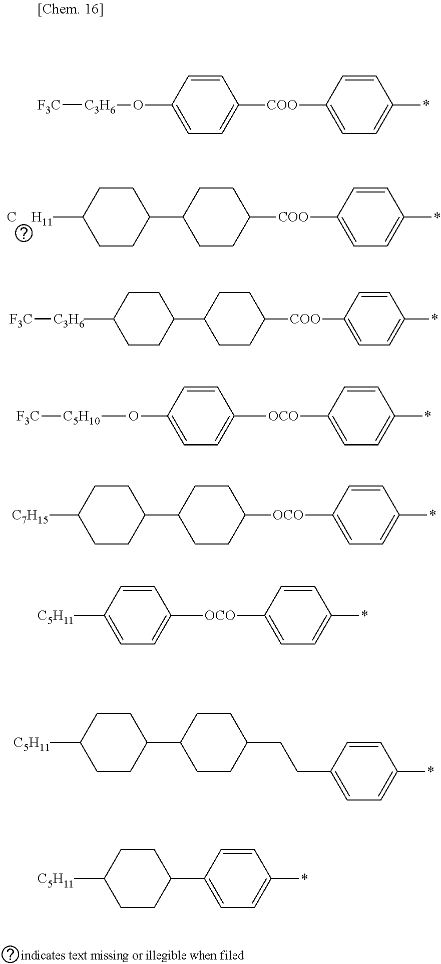

(In the formula, “*” represents a bond.)

The polymer [Q] can be synthesized according to a known method of the related art. For example, in a case where the polymer [Q] is a polyamic acid, the tetracarboxylic dianhydride and the diamine compound which are exemplified in the description of the polymer [P] are reacted. At this time, a diamine having a vertically alignable group is used as at least a part of the diamine compound and polymerized, and thereby the polymer [Q] is obtained. Specific examples of diamines having a vertically alignable group include the side chain type diamines exemplified in the description of the polymer [P], and the like. A polyimide as the polymer [Q] can be obtained by dehydrating and condensing a polyamic acid to be obtained by the above polymerization.

An amount of the vertically alignable group included in the polymer [Q] is preferably 0.05 mol % or more, more preferably 0.05 to 70 mol %, and even more preferably 0.1 to 50 mol % with respect to a total amount of all structural units of the polymer component, from the viewpoint that then, a decrease in dielectric constant is sufficiently inhibited. For example, in a case where the polymer [Q] is at least one selected from the group consisting of a polyamic acid, a polyamic acid ester, and a polyimide, a proportion of the diamine having a vertically alignable group used is preferably 0.1 to 70 mol %, more preferably 0.2 to 60 mol %, and even more preferably 0.5 to 50 mol % with respect to a total amount of diamine compounds used in the polymerization. As the diamine having a vertically alignable group, one kind may be used alone, or two or more kinds thereof may be used in combination.

<Polyimide>

In a case where the liquid crystal aligning agent contains a polyimide, the polyimide may have at least one of a specific partial structure and a vertically alignable group, and may be a polymer not having both a specific partial structure and a vertically alignable group. In a case where the liquid crystal aligning agent contains a polyimide, a content ratio of polyimide (a total amount thereof in a case where two or more kinds thereof are included) is preferably 20% by mass or more, more preferably 50% by mass or more, and even more preferably 70% by mass or more with respect to a total amount of polymer components contained in the liquid crystal aligning agent, from the viewpoint that then, it is possible to sufficiently improve reliability of an antenna device for long-term operation. As the polyimide, one kind may be used alone, or two or more kinds thereof may be used in combination.

<Crosslinking Agent>

A case in which the liquid crystal aligning agent contains a compound (hereinafter referred to as a “crosslinking agent”) which has a crosslinkable group is preferable from the viewpoint that then, it is possible to improve reliability of a liquid crystal alignment film, and thereby improve reliability of an antenna device for long-term operation.

The crosslinkable group is a group capable of forming a covalent bond between the same or different molecules by light or heat. Specific examples thereof include a (meth)acryloyl group, a group having a vinyl group (an alkenyl group, a vinylphenyl group, and the like), an ethynyl group, an epoxy group (an oxiranyl group, an oxetanyl group), a carboxyl group, a (protected) isocyanate group, an acid anhydride group, and the like. The term “(meth)acryloyl” includes acryloyl and methacryloyl. The number of crosslinkable groups included in the crosslinking agent may be one or more. The number thereof is preferably two or more and more preferably two to six from the viewpoint that then, reliability of a liquid crystal alignment film is sufficiently improved.

Specific examples of crosslinking agents are as follows: allyl-group-containing compounds such as diallyl phthalate;

(meth)acrylic compounds such as ethylene glycol di(meth)acrylate, propylene glycol di(meth)acrylate, diethylene glycol di(meth)acrylate, 1,6-hexanediol di(meth)acrylate, pentaerythritol tri(meth)acrylate, ditrimethylolpropane tetra(meth)acrylate, pentaerythritol tetra(meth)acrylate, trimethylolpropane (meth)acrylate, ethoxylated trimethylolpropane tri(meth)acrylate, dipentaerythritol hexa(meth) acrylate, ethylene glycol tri(meth)acrylate, polyether (meth)acrylate, ethoxylated bisphenol A di(meth)acrylate, tricyclodecane dimethanol di(meth)acrylate, and 2-methyl-1,8-octanediol di(meth)acrylate;

carboxylic acids such as maleic acid, itaconic acid, trimellitic acid, tetracarboxylic acid, cis-1,2,3,4-tetrahydrophthalic acid, ethylene glycol bistrimate, propylene glycol bistrimate, 4,4′-oxydiphthalic acid, and trimellitic anhydride;

epoxy compounds such as ethylene glycol diglycidyl ether, polyethylene glycol diglycidyl ether, propylene glycol diglycidyl ether, tripropylene glycol diglycidyl ether, polypropylene glycol diglycidyl ether, 1,6-hexanediol diglycidyl ether, glycerin diglycidyl ether, 2,2-bis(4-hydroxyphenyl)propane diglycidyl ether, trimethylolpropane triglycidyl ether, N,N,N′,N′-tetraglycidyl-m-xylylenediamine, 1,3-bis(N,N-diglycidylaminomethyl)cyclohexane, N,N,N′,N′-tetraglycidyl-4,4′-diaminodiphenylmethane, N,N-diglycidyl-benzylamine, N,N-diglycidyl-aminomethylcyclohexane, and N,N-diglycidyl-cyclohexylamine;

(protected) isocyanate compounds in which a polyvalent isocyanate such as tolylene diisocyanate, hexamethylene diisocyanate, and diphenylmethylene diisocyanate is protected by a protecting group; and the like.

A formulation proportion of the crosslinking agent is preferably 0.05 parts by mass or more, more preferably 0.1 part by mass or more, and even more preferably 1 part by mass or more with respect to 100 parts by mass of polymer components used for preparing the liquid crystal aligning agent, from the viewpoint that then, an effect of improving reliability of a liquid crystal alignment film is sufficiently obtained. The upper limit value of the formulation proportion of the crosslinking agent is preferably 40 parts by mass or less and more preferably 30 parts by mass or less. As the crosslinking agent, one kind may be used alone, or two or more kinds thereof may be used in combination.

<Solvent>

As a solvent component of the liquid crystal aligning agent, it is preferable to use a mixed solvent of a first solvent having high solubility and levelability and a second solvent having favorable wettability and spreadability.

Specific examples of the first solvent include N-methyl-2-pyrrolidone, N-ethyl-2-pyrrolidone, 1,2-dimethyl-2-imidazolidinone, γ-butyrolactone, γ-butyrolactam, N,N-dimethylformamide, N,N-dimethylacetamide, 4-hydroxy-4-methyl-2-pentanone, diisobutyl ketone, ethylene carbonate, propylene carbonate, and the like.

Specific examples of the second solvent include ethylene glycol monomethyl ether, butyl lactate, butyl acetate, methyl methoxypropionate, ethyl ethoxypropionate, ethylene glycol methyl ether, ethylene glycol ethyl ether, ethylene glycol-n-propyl ether, ethylene glycol-i-propyl ether, ethylene glycol-n-butyl ether (butyl cellosolve), ethylene glycol dimethyl ether, ethylene glycol ethyl ether acetate, diethylene glycol dimethyl ether, diethylene glycol diethyl ether, diethylene glycol monomethyl ether, diethylene glycol monoethyl ether, diethylene glycol monomethyl ether acetate, diethylene glycol monoethyl ether acetate, isoamyl propionate, isoamyl isobutyrate, diisopentyl ether, and the like. As the solvent, one kind may be used alone, or two or more kinds thereof may be used in combination.

In addition, as a solvent component of the liquid crystal aligning agent, at least one low-boiling-point solvent selected from the group consisting of ether/alcohol solvents, ester solvents, and ketone solvents which have a boiling point of 180° C. or less at 1 atm may be used. Specific examples of ether/alcohol solvents include propylene glycol monomethyl ether, diethylene glycol methyl ethyl ether, 3-methoxy-1-butanol, ethylene glycol monomethyl ether, ethylene glycol monoethyl ether, ethylene glycol monopropyl ether, ethylene glycol-n-butyl ether (butyl cellosolve), ethylene glycol dimethyl ether, diethylene glycol dimethyl ether, and the like. Specific examples of ester solvents include propylene glycol monomethyl ether acetate, ethylene glycol ethyl ether acetate, and the like.

Specific examples of ketone solvents include cyclobutanone, cyclopentanone, cyclohexanone, diisobutyl ketone, and the like.

In a case of using the low-boiling-point solvent, a content ratio thereof is preferably 40% by mass or more and more preferably 50% by mass or more with respect to a total amount of the solvent in the liquid crystal aligning agent.

In addition to the above examples, as other components contained in the liquid crystal aligning agent, other polymers other than the above-described polymers, antioxidants, metal chelate compounds, curing accelerators, surfactants, fillers, dispersants, photosensitizers, and the like are exemplified. A formulation proportion of the other components can be appropriately selected according to each compound within a range not impairing the effects of the present disclosure.

(Polymer Having Photo-Alignable Group)

In a case where a liquid crystal alignment film is formed using a photo alignment method, the liquid crystal aligning agent preferably contains a polymer having a photo-alignable group (hereinafter referred to as a “photo-alignable-group-containing polymer”). The photo-alignable group is a functional group that imparts anisotropy to a film by a photoisomerization reaction, a photodimerization reaction, a photo-Fries rearrangement reaction, or a photodecomposition reaction by light irradiation. Specific examples of photo-alignable groups include an azobenzene-containing group containing azobenzene or a derivative thereof as a basic skeleton, a cinnamic-acid-structure-containing group containing cinnamic acid or a derivative thereof (a cinnamic acid structure) as a basic skeleton, a chalcone-containing group containing chalcone or a derivative thereof as a basic skeleton, a benzophenone-containing group containing benzophenone or a derivative thereof as a basic skeleton, a phenylbenzoate-containing group containing phenylbenzoate or a derivative thereof as a basic skeleton, a coumarin-containing group containing coumarin or a derivative thereof as a basic skeleton, a cyclobutane-containing group containing cyclobutane or a derivative thereof as a basic skeleton, and the like. It is particularly preferable that the photo-alignable-group-containing polymer have a cinnamic-acid-structure-containing group among the above examples from the viewpoint that then, photoreactivity can be sufficiently increased, and the group can be easily introduced into the polymer.

In a case where the photo-alignable-group-containing polymer has the cinnamic-acid-structure-containing group, the photo-alignable-group-containing polymer preferably has a partial structure represented by Formula (5).

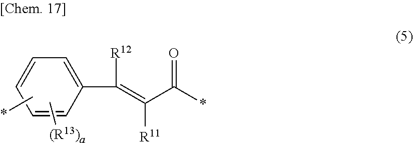

(In Formula (5), R¹¹ and R¹² are each independently a hydrogen atom, a halogen atom, an alkyl group having 1 to 3 carbon atoms, or an alkoxy group or cyano group which has 1 to 3 carbon atoms; R¹³ is a halogen atom, an alkyl group having 1 to 3 carbon atoms, or an alkoxy group or cyano group which has 1 to 3 carbon atoms; a is an integer of 0 to 4, where a plurality of R¹³'s may be the same as or different from each other in a case where a is 2 or greater; and “*” represents a bond.)

The photo-alignable-group-containing polymer may be the compound [M], but from the viewpoint that energy loss can be sufficiently reduced and photoreactivity can be sufficiently ensured, the polymer is preferably a polymer different from the compound [M], that is, a polymer not having a specific partial structure. In a case where the photo-alignable-group-containing polymer is a polymer not having a specific partial structure, a main skeleton thereof is not particularly limited, but at least one selected from the group consisting of a polyamic acid, a polyamic acid ester, a polyimide, and a polyorganosiloxane is preferable. In a case where the photo-alignable-group-containing polymer is contained in the liquid crystal aligning agent, a formulation proportion thereof is preferably 1% by mass or more and more preferably 2% by mass or more with respect to a total amount of polymer components in the liquid crystal aligning agent. In addition, the upper limit value of the formulation proportion of the photo-alignable-group-containing polymer is preferably 50% by mass or less and more preferably 30% by mass or less.

A method for synthesizing the photo-alignable-group-containing polymer is not particularly limited, and may be appropriately selected according to a main skeleton of the polymer. Specific examples thereof include a method (1) of polymerizing using a monomer having a photo-alignable group; a method (2) of synthesizing a polymer having a first functional group (for example, an epoxy group or the like) in a side chain, and reacting a compound having a second functional group (for example, a carboxyl group or the like) which is capable of reacting with the first functional group and having a photo-alignable group with the polymer having the first functional group; and the like. In a case where the photo-alignable-group-containing polymer is a polyorganosiloxane, it is preferable to use the method (2) from the viewpoint that then, efficiency of introduction into a side chain becomes high.

A concentration of solid contents (a ratio of a total mass of components other than the solvent of the liquid crystal aligning agent to a total mass of the liquid crystal aligning agent) in the liquid crystal aligning agent is appropriately selected in consideration of viscosity, volatility, and the like, and the concentration of solid contents is preferably within a range of 1% to 10% by mass. In a case where a concentration of solid contents is less than 1% by mass, a thickness of a coating film becomes excessively thin, and it becomes difficult to obtain a favorable liquid crystal alignment film. On the other hand, in a case where a concentration of solid contents exceeds 10% by mass, a thickness of a coating film becomes excessively thick, and it becomes difficult to obtain a favorable liquid crystal alignment film, and furthermore, viscosity of the liquid crystal aligning agent increases, thereby deteriorating application properties.

(Method of Forming Liquid Crystal Alignment Film)

Next, a method of forming liquid crystal alignment films (the first alignment film 22 and the second alignment film 23) on a substrate using the above-mentioned liquid crystal aligning agent will be described. A liquid crystal alignment film is formed by applying the liquid crystal aligning agent on a substrate to form a coating film, and subjecting the coating film to an alignment treatment as needed.

### [Step 1: Formation of Coating Film]

Application of the liquid crystal aligning agent to substrates (the patch substrate 12 and the slotted substrate 13) can be performed by an appropriate application method.

Specifically, for example, it is possible to employ a roll coater method, a spinner method, an ink jet printing method, a flexographic printing method, a bar coater method, an extrusion die method, a direct gravure coater method, a chamber doctor coater method, an offset gravure coater method, an impregnated coater method, an MB coater method, a slit coat method, or the like. A case of using a slit coat method in application of the liquid crystal aligning agent to the patch substrate 12 and the slotted substrate 13 is preferable from the viewpoint that then, favorable application properties can be ensured.

After applying the liquid crystal aligning agent, it is preferable to heat (bake) an applied surface. In a heating step, pre-heating (pre-baking) is preferably performed for the purpose of preventing the applied liquid crystal aligning agent from dripping. A pre-baking temperature is preferably 30° C. to 200° C., and a pre-baking time is preferably 0.25 to 10 minutes. After the pre-baking, firing (post-baking) is performed for the purpose of completely removing the solvent and, if necessary, thermally imidizing an amic acid structure present in the polymer. In this case, a firing temperature (a post-baking temperature) is preferably 80° C. to 300° C. The temperature is more preferably 160° C. or lower, and even more preferably 80° C. to 150° C. A heating time is preferably 0.1 to 30 minutes and more preferably 1 to 15 minutes. A thickness of a film to be formed is preferably 0.01 to 3 μm. After applying the liquid crystal aligning agent to the substrate, an organic solvent is removed, and thereby a liquid crystal alignment film, or a coating film serving as the liquid crystal alignment film is formed.

### [Step 2: Photo Alignment Treatment]

In a case where liquid crystals have twist alignment or homogenous alignment, a treatment (an alignment treatment) for imparting a liquid crystal aligning capability to the coating film formed in Step 1 is performed. Thereby, a liquid crystal alignment film in which a liquid crystal molecule aligning capability is imparted to the coating film is formed. Examples of alignment treatments include a rubbing treatment for imparting a liquid crystal aligning capability to a coating film by rubbing the coating film in a certain direction with a roll wrapped with a cloth made of fibers such as nylon, rayon, and cotton; a photo alignment treatment for imparting a liquid crystal aligning capability to a coating film by irradiating the coating film formed on a substrate with light; and the like. Meanwhile, in a case where liquid crystals have homeotropic alignment, the coating film formed in Step 1 can be used as it is as a liquid crystal alignment film, but the coating film may be subjected to an alignment treatment.

In the photo alignment treatment, examples of light with which the coating film is irradiated include ultraviolet rays including light having a wavelength of 150 to 800 nm, visible light rays, and the like. Among the above examples, ultraviolet rays including light having a wavelength of 300 to 400 nm are preferable. Light for irradiation may be polarized or unpolarized. As polarized light, it is preferable to use light containing linearly polarized light. In a case where light to be used is polarized light, light irradiation may be performed from a direction perpendicular to a substrate surface, may be performed from a direction oblique thereto, or may be performed using a combination thereof. In a case where of irradiation with non-polarized light, light irradiation is performed from a direction oblique to a substrate surface.

Examples of light sources used include a low-pressure mercury lamp, a high-pressure mercury lamp, a deuterium lamp, a metal halide lamp, an argon resonance lamp, a xenon lamp, a mercury-xenon lamp (an Hg-Xe lamp), and the like. Polarized light can be obtained from means using these light sources in combination with, for example, a filter, a diffraction grating, and the like. An amount of light for irradiation is preferably 0.1 mJ/cm² to 1,000 mJ/cm², and more preferably 1 to 500 mJ/cm².

### Other Embodiments

The content of the present disclosure is not limited to the above embodiment, and may be implemented, for example, as follows.
In the above embodiment, the liquid crystal alignment film is formed on both the patch substrate 12 and the slotted substrate 13, but the liquid crystal alignment film may be formed on only one of the patch substrate 12 and the slotted substrate 13. However, it is preferable to provide the liquid crystal alignment film on both the patch substrate 12 and the slotted substrate 13 as shown in FIG. 2 from the viewpoint that then, an effect of lowering dielectric loss of the array antenna 10 can be further enhanced.
In the above embodiment, the radial line slot antenna has been described as an example, but the array antenna 10 is not limited thereto, and arrangement of the antenna units 11 and the slots 21 is not limited to the above descriptions. For example, a pair of the slots extending in a direction crossing each other may be spirally disposed, and the antenna units 11 may be spirally disposed. Alternatively, the antenna units 11 may be disposed in a matrix.

### EXAMPLES

Hereinafter, the present disclosure will be specifically described with reference to examples, but the present disclosure is not limited to these examples.

In the following examples, a weight-average molecular weight Mw, a number average molecular weight Mn, and epoxy equivalent of the polymer, and a solution viscosity of a polymer solution were measured by the following methods. The necessary amounts of raw material compounds and polymers used in the following examples were secured by repeating synthesis on the synthesis scale shown in the following synthesis examples as necessary.

### [Weight-Average Molecular Weight Mw and Number Average Molecular Weight Mn of Polymer]

Mw and Mn are values in terms of polystyrene which were measured by GPC under the following conditions.

Column: TSKgel GRCXLII manufactured by TOSOH CORPORATION

Solvent: tetrahydrofuran

Temperature: 40° C.

Pressure: 68 kgf/cm²

[Epoxy equivalent]

Epoxy equivalent was measured by a hydrochloric acid-methyl ethyl ketone method described in JIS C 2105.

### [Solution Viscosity of Polymer Solution]

A solution viscosity (mPa·s) of the polymer solution was measured at 25° C. using an E-type rotational viscometer.

The abbreviations of compounds used in the following examples are as follows.

(Tetracarboxylic Dianhydride and Diamine)

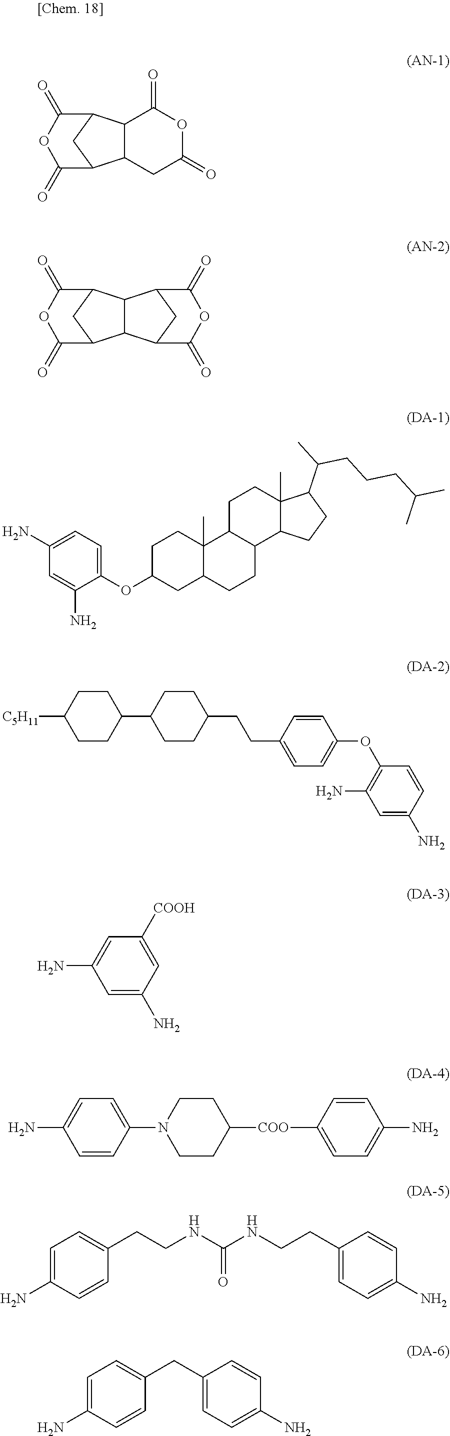

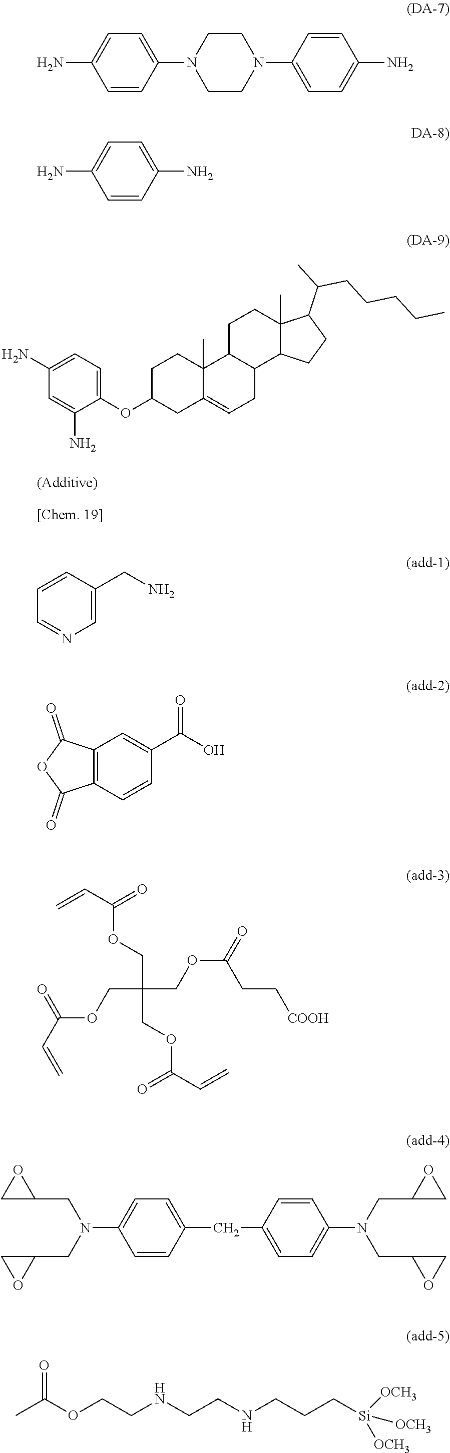

### Synthesis Example 1

A cinnamic acid derivative (C-1) was synthesized according to Scheme 1.

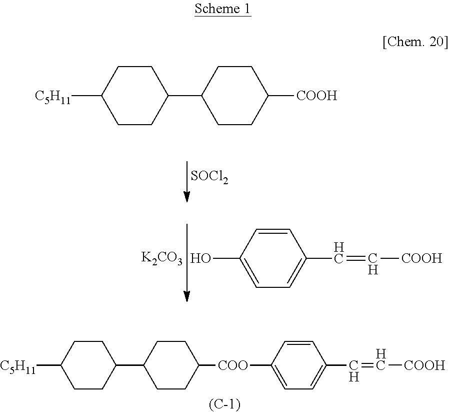

14 g of trans-4-pentyl-bicyclohexanecarboxylic acid was placed in a reaction vessel, 1 L of thionyl chloride and 0.77 mL of N,N-dimethylformamide were added thereto, and the mixture was stirred at 80° C. for 1 hour. Next, thionyl chloride was distilled off under reduced pressure, and methylene chloride was added. The mixture was washed with an aqueous solution of sodium bicarbonate, dried over magnesium sulfate, and concentrated. Thereafter, tetrahydrofuran was added to obtain a solution.

Next, 74 g of 4-hydroxycinnamic acid, 138 g of potassium carbonate, 4.8 g of tetrabutylammonium, 500 mL of tetrahydrofuran, and 1 L of water were put into another 5 L three-neck flask. The aqueous solution was ice-cooled, a tetrahydrofuran solution containing a reaction product of trans-4-pentyl-bicyclohexanecarboxylic acid and thionyl chloride was slowly added dropwise, and the reaction was further performed while stirring for 2 hours. After completion of the reaction, the reaction mixture was neutralized by adding hydrochloric acid and extracted with ethyl acetate. Thereafter, the extraction liquid was dried over magnesium sulfate, concentrated, and then recrystallized with ethanol. Thereby, 15 g of white crystals of the cinnamic acid derivative (C-1) was obtained.

### Synthesis Example 2

A cinnamic acid derivative (C-2) was synthesized according to Scheme 2.

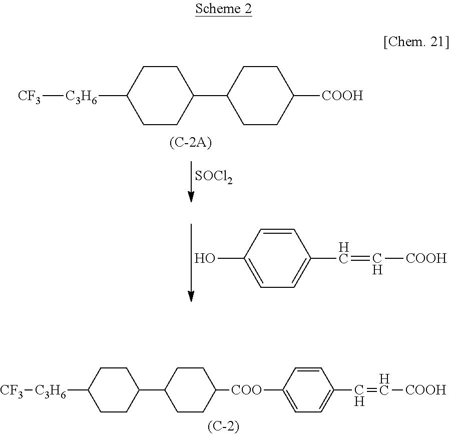

To a 100 mL eggplant flask equipped with a reflux tube and a nitrogen introduction pipe, 4.63 g of the compound represented by Formula (C-2A), 50 mL of thionyl chloride, and 0.05 mL of N,N-dimethylformamide were added and refluxed for 1 hour. After the completion of the reaction, the mixture was concentrated to dryness under reduced pressure, and 75 mL of tetrahydrofuran was added thereto (this is referred to as the “D-1 solution”). Meanwhile, to a 100 mL three-neck flask equipped with a thermometer and a nitrogen introduction pipe, 2.62 g of hydroxycinnamic acid, 4.41 g of potassium carbonate, 38 mL of water, 19 mL of tetrahydrofuran, and 0.15 g of tetrabutylammonium bromide were added, and the mixture was ice-cooled to 5° C. or lower. Subsequently, the previously prepared “D-1 solution” was added dropwise over 30 minutes. Thereafter, the temperature was returned to room temperature, and the mixture was stirred for 4 hours. After the reaction was completed, 100 mL of ethyl acetate and 200 mL of 1N hydrochloric acid were added to wash the mixture, and the mixture was washed three times with 100 mL of water. Next, an organic layer was dried over magnesium sulfate, and then filtered and concentrated under reduced pressure. The precipitated white crystals thus obtained were filtered and dried, and thereby 1.8 g of a compound (C-2) was obtained.

### Synthesis of Polysiloxane Having Epoxy Group

### Synthesis Example 3

In a reaction vessel equipped with a stirrer, thermometer, a dropping funnel, and a reflux condenser, 100.0 g of 2-(3,4-epoxycyclohexyl)ethyltrimethoxysilane (ECETS), 500 g of methyl isobutyl ketone, and 10.0 g of triethylamine were put and mixed at room temperature. Next, 100 g of deionized water was dropped from the dropping funnel over 30 minutes, and then the mixture was reacted at 80° C. for 6 hours while being mixed under reflux. After the completion of the reaction, an organic layer was taken out and washed with an aqueous solution of 0.2% by mass ammonium nitrate until the washed water became neutral. Thereafter, the solvent and water were distilled off under reduced pressure, and thereby a polysiloxane having an epoxy group (which is referred to as the “polysiloxane (SEp-1)”) was obtained as a viscous transparent liquid. ¹H-NMR analysis of the polysiloxane (SEp-1) was performed, and it was revealed that a peak based on an epoxy group was obtained at a chemical shift (δ) of around 3.2 ppm, and it was confirmed that no side reaction due to the epoxy group occurred during the reaction. A weight-average molecular weight (Mw) of the polysiloxane (SEp-1) was Mw=2,200, and epoxy equivalent was 186 g/mol.

### Synthesis of Polysiloxane Having Photo-Alignable Group

### Synthesis Example 4

To a 200 mL three-neck flask, 11.6 g of the polysiloxane (SEp-1) obtained in Synthesis Example 3, 80 g of methyl isobutyl ketone, 4.0 g of the cinnamic acid derivative (C-1) (corresponding to 15 mol % with respect to the epoxy groups of the polysiloxane (SEp-1)), 4.8 g of the cinnamic acid derivative (C-2) (corresponding to 15 mol % with respect to the epoxy groups of the polysiloxane (SEp-1)), and 0.10 g of UCAT 18X (trade name, a curing agent for epoxy compounds manufactured by San-Apro Ltd.) were put, and a reaction was carried out while stirring at 100° C. for 48 hours. After completion of the reaction, methanol was added to the reaction mixture to generate a precipitate. A solution obtained by dissolving the obtained precipitate in ethyl acetate was washed three times with water, and an organic layer was dried over magnesium sulfate. Thereafter, the solvent was distilled off, and thereby 18.3 g of white powders of polysiloxane (POS-1) was obtained. A weight-average molecular weight Mw of the polysiloxane (POS-1) was 5,000.

### Synthesis of Polyamic Acid and Polyimide

### Synthesis Example 5

21.288 g of 2,3,5-tricarboxycyclopentylacetic acid dianhydride (98 mol parts with respect to 100 mol parts of a total amount of diamines used in the synthesis, the same applies hereinafter) as a tetracarboxylic dianhydride; and 4.794 g (10 mol parts) of cholestanyloxy-2,4-diaminobenzene, 8.967 g (20 mol parts) of 4-{4-[2-(4′-pentyl-1,1′-bicyclohexyl)ethyl]phenoxy}benzene-1,3-diamine, 5.897 g (40 mol parts) of 3,5-diaminobenzoic acid, and 9.052 g (30 mol parts) of 4-(4-aminophenoxycarbonyl)-1-(4-aminophenyl)piperidine as diamine compounds were dissolved in 200 g of N-methyl-2-pyrrolidone (NMP) and reacted at 30° C. for 6 hours. Next, the reaction mixture was poured into a large excess of methanol to allow a reaction product to precipitate. The recovered precipitate was washed with methanol and then dried at 40° C. under reduced pressure for 15 hours, and thereby 40 g of polyamic acid (hereinafter referred to as a polymer (PA-1)) was obtained. The obtained polymer (PA-1) was prepared with NMP so that a concentration thereof became 20% by mass. When viscosity of this solution was measured, it was 1410 mPa·s. In addition, when this polymer solution was allowed to stand at 20° C. for 3 days, it did not gel, and storage stability was favorable.

### Synthesis Example 6

Polymerization was performed in the same manner as in Synthesis Example 5, and thereby a polyamic acid solution having a polymer concentration of 25% by mass was obtained. 250 g of NMP was added to the obtained polyamic acid solution. Thereafter, 14.25 g of acetic acid anhydride and 11.04 g of pyridine were added and reacted at 60° C. for 4 hours. Next, the reaction mixture was poured into a large excess of methanol to allow a reaction product to precipitate. The recovered precipitate was washed with methanol and then dried at 100° C. under reduced pressure, and thereby a polyimide (hereinafter referred to as a polymer (PI-1)) was obtained. An imidization ratio of the obtained polyimide was 55%. In addition, the obtained polymer (PI-1) was prepared with NMP so that a concentration thereof became 20% by mass. When viscosity of this solution was measured, it was 461 mPa·s.

### Synthesis Examples 7 and 8

Polyimides (a polymer (PI-2) and a polymer (PI-3)) were prepared in the same manner as in Synthesis Example 6 except that the types and amounts of tetracarboxylic dianhydride and diamine used in the polymerization were changed as shown in Table 1. The obtained polyimide was prepared with NMP so that a concentration thereof became 20% by mass. A solution viscosity measured thereafter is shown in Table 1 together with an imidization ratio.

### Synthesis Examples 9 and 11

Polyamic acids (a polymer (PA-2) and a polymer (PA-3)) were prepared in the same manner as in Synthesis Example 5 except that the types and amounts of tetracarboxylic dianhydride and diamine used in the polymerization were changed as shown in Table 1. The obtained polyamic acid was prepared with NMP so that a concentration thereof became 20% by mass. A solution viscosity measured thereafter is shown in Table 1.

### Synthesis Example 10

16.5 g of 2,3,5-tricarboxycyclopentylacetic acid dianhydride (98 mol parts with respect to 100 mol parts of a total amount of diamines used in the synthesis, the same applies hereinafter) as a tetracarboxylic dianhydride; and 8.0 g (99.5 mol parts) of paraphenylenediamine and 0.2 g (0.5 mol parts) of cholesteryloxy-2,4-diaminobenzene as diamine compounds were dissolved in 225 g of N-methyl-2-pyrrolidone (NMP) and reacted at 60° C. for 1 hour. Thereafter, 250 g of N-methyl-2-pyrrolidone (NMP), 29.11 g of pyridine, and 22.54 g of acetic acid anhydride were added, and a dehydration and ring-closure reaction was performed at 110° C. for 5 hours.

Next, the reaction mixture was poured into a large excess of methanol to allow a reaction product to precipitate. The recovered precipitate was washed with methanol and dried at 40° C. under reduced pressure for 15 hours, and thereby 43 g of a polyimide (PI-4) having an imidization ratio of about 90% was obtained. The obtained polymer (PI-4) was prepared with NMP so that a concentration thereof became 10% by mass. When viscosity of this solution was measured, it was 410 mPa·s. In addition, when this polymer solution was allowed to stand at 20° C. for 3 days, it did not gel, and storage stability was favorable.

TABLE 1

| | | Synthesis | Synthesis | Synthesis | Synthesis | Synthesis | Synthesis | Synthesis |
|---|---|---|---|---|---|---|---|---|
| Monomer | | Example 5 | Example 6 | Example 7 | Example 8 | Example 9 | Example 10 | Example 11 |
| Acid | AN-1 | 100 | 100 | 0 | 100 | 50 | 100 | 50 |
| dianhydride | AN-2 | 0 | 0 | 100 | 0 | 50 | 0 | 50 |
| Diamine | DA-1 | 10 | 10 | 0 | 0 | 0 | 0 | 0 |
| | DA-2 | 20 | 20 | 0 | 0 | 0 | 0 | 0 |
| | DA-3 | 40 | 40 | 40 | 50 | 20 | 0 | 30 |
| | DA-4 | 30 | 30 | 0 | 0 | 30 | 0 | 0 |
| | DA-5 | 0 | 0 | 0 | 30 | 20 | 0 | 0 |
| | DA-6 | 0 | 0 | 60 | 20 | 20 | 0 | 20 |
| | DA-7 | 0 | 0 | 0 | 0 | 10 | 0 | 0 |
| | DA-8 | 0 | 0 | 0 | 0 | 0 | 99.5 | 50 |
| | DA-9 | 0 | 0 | 0 | 0 | 0 | 0.5 | 0 |

| | | | | | | | |
|---|---|---|---|---|---|---|---|
| Solution viscosity of | 1410 | 461 | 340 | 932 | 801 | 410 | 420 |
| polymer solution | | | | | | | |
| [mPa · s) | | | | | | | |
| Imidization ratio [%] | — | 55 | 20 | 30 | — | 90 | — |
| Polymer name | PA-1 | PI-1 | PI-2 | PI-3 | PA-2 | PI-4 | PA-3 |

In Table 1, values in the column of acid dianhydride indicate a proportion (mol parts) of each of the compounds used with respect to a total amount of 100 mol parts of tetracarboxylic dianhydride used in the polymerization, and values in the column of diamine indicate a proportion (mol parts) of each of the compounds used with respect to a total of 100 mol parts of diamine used in the polymerization.

<Preparation of Liquid Crystal Composition>

A compound represented by Formula (LC-1) was produced according to a method described in Liq. Cryst., 27 (2), (2000), p. 283-287. A compound represented by Formula (LC-2) was produced according to a method disclosed in PCT International Publication No. WO2011/066905. Next, 0.95 g of the compound represented by Formula (LC-1) and 0.05 g of the compound represented by Formula (LC-2) were mixed to obtain a liquid crystal composition Q.

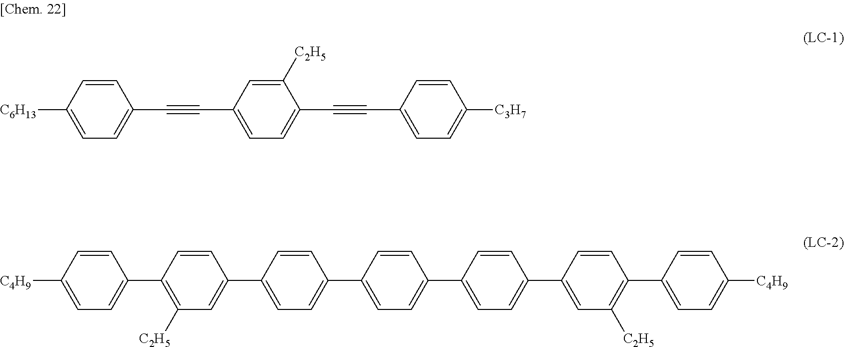

### Example 1

<Preparation of Liquid Crystal Aligning Agent>

As a polymer component, N-methyl-2-pyrrolidone (NMP) and butyl cellosolve (BC) were added as solvents to the polymer (PI-1) obtained in Synthesis Example 6 to prepare such that a concentration of solid content became 6% by mass, and a mass ratio of each solvent became NMP:BC=45:55. Next, the obtained polymer solution was filtered with a filter having a pore size of 0.2 μm, and thereby a liquid crystal aligning agent (A-1) was prepared.

<Evaluation of Antennas; Regarding Application to Microwave Region>

1. Production of Array Antenna

The array antenna 10 shown in FIGS. 1 and 2 was produced. The liquid crystal alignment films (the first alignment film 22 and the second alignment film 23) were formed using the liquid crystal aligning agent (A-1), and the liquid crystal layer 14 was formed using the liquid crystal composition Q prepared above. The formation of the liquid crystal alignment films was performed as follows.

Formation of Liquid Crystal Alignment Films

Using a spinner, the liquid crystal aligning agent (A-1) was applied to each of surfaces of the patch substrate 12 and the slotted substrate 13 on which electrodes were to be formed. Next, the substrates to which the liquid crystal aligning agent (A-1) were applied were pre-baked on a hot plate at 80° C. for 2 minutes to form a coating film. Next, these substrates were heated (post-baked) at 160° C. for 5 minutes in an oven of which the inside was replaced with nitrogen. Thereby, liquid crystal alignment films each having an average film thickness of 0.5 μm were formed on the respective substrates.

2. Evaluation of Dielectric Loss Tangent

A dielectric loss tangent (tan δ) was measured using a perturbation-type space resonator manufactured by KEYCOM Corporation under conditions of a temperature of 25° C. and a frequency of 30 GHz. The array antenna produced in the above section 1. was connected to a personal computer via the resonator and a vector network analyzer, and the measurement was performed at a measurement frequency of 30 GHz and a measurement environment temperature of 25° C. Values of the dielectric loss tangent were obtained from a difference between a resonance frequency and a Q value for a case in which a sample was inserted into the resonator and a case in which the sample was not inserted. The results were evaluated as “favorable” in a case where a value was less than 0.0015, “acceptable” in a case where a value was less than 0.0030 and 0.0015 or more, and “unacceptable” in a case where a value was 0.0030 or more. As a result, a dielectric loss tangent of the array antenna of this example was 0.0009, which was evaluated as “favorable.”

3. Evaluation of Durability of Antennas (Evaluation of Reliability)

A voltage of 10 V was continuously applied to the array antenna produced in the above section 1 for 100 hours. Thereafter, a dielectric loss tangent (tan δ) was measured under conditions of a temperature of 25° C. and a frequency of 30 GHz in the same manner as the above section 2. Evaluation of dielectric loss tangent. The results were evaluated as “favorable” in a case where a value was less than 0.0015, “acceptable” in a case where a value was less than 0.0030 and 0.0015 or more, and “unacceptable” in a case where a value was 0.0030 or more. As a result, a dielectric loss tangent of the array antenna was 0.0011, which was evaluated as “favorable.”

### Examples 2 to 8 and Comparative Example 1

Liquid crystal aligning agents (A-2) to (A-9) were respectively prepared in the same operation manner as in the preparation of the liquid crystal aligning agent (A-1) except that the type and a formulation amount shown in Table 2 were used for each of the component. In addition, the array antenna was evaluated in the same manner as in Example 1 using the liquid crystal aligning agent (A-4) (Example 4). Furthermore, evaluation was performed in Examples 3 and 4 in the same manner as in Example 1, except that, in Example 3, a coating film formed using the liquid crystal aligning agent (A-3) was subjected to an alignment treatment by a photo alignment method, and in Examples 4 to 8 and Comparative Example 1, coating films respectively formed using the liquid crystal aligning agents (A-4) to (A-9) were subjected to a rubbing alignment treatment. The results are shown in Table 2. The liquid crystal aligning agent (A-3) is a material suitable for a photo alignment treatment, the liquid crystal aligning agents (A-4) to (A-6) and (A-8) are materials suitable for a homogeneous alignment, and the liquid crystal aligning agent (A-7) is a material suitable for a twist alignment.

TABLE 2

| | | Liquid crystal aligning agent | | | | | | | | | |
|---|---|---|---|---|---|---|---|---|---|---|---|
| | | Polymer 1 | | Polymer 2 | | Additive | | | | | |
| | Type of | | Amount | | Amount | | Amount | Characteristics of antennas | | | |
| | aligning | | (parts by | | (parts by | | (parts by | Dielectric loss tangent | | Evaluation of durability | |
| | agent | Type | mass) | Type | mass) | Type | mass) | tan δ | Determination | tan δ | Determination |
| Example 1 | A-1 | PI-1 | 100 | — | — | — | — | 0.0009 | Favorable | 0.0011 | Favorable |
| Example 2 | A-2 | PI-2 | 100 | — | — | add-1 | 5 | 0.0010 | Favorable | 0.0011 | Favorable |
| Example 3 | A-3 | PI-1 | 100 | POS-1 | 5 | add-2 | 0.1 | 0.0011 | Favorable | 0.0014 | Favorable |
| Example 4 | A-4 | PA-1 | 100 | — | — | — | — | 0.0013 | Favorable | 0.0016 | Acceptable |
| Example 5 | A-5 | PI-3 | 100 | — | — | add-3 | 20 | 0.0009 | Favorable | 0.0011 | Favorable |
| Example 6 | A-6 | PA-2 | 100 | — | — | add-4 | 2 | 0.0011 | Favorable | 0.0011 | Favorable |
| Example 7 | A-7 | PI-4 | 100 | — | — | add-5 | 0.5 | 0.0009 | Favorable | 0.0010 | Favorable |
| Example 8 | A-8 | PI-2 | 100 | — | — | — | — | 0.0017 | Acceptable | 0.0011 | Favorable |
| Comparative | A-9 | PA-3 | 100 | — | — | — | — | 0.0049 | Unacceptable | 0.0083 | Unacceptable |
| Example 1 | | | | | | | | | | | |

As shown in Table 2, tan δ was 0.0013 or less, and the evaluation was “favorable” in Examples 1 to 7; and the evaluation was “acceptable” in Example 8. In addition, durability was “favorable” in Examples 1 to 3 and 5 to 8, and the evaluation was “acceptable” in Example 4. On the other hand, in Comparative Example 1, tan δ was 0.0049, which was a value larger than those of Examples 1 to 8. Furthermore, the evaluation of durability was “unacceptable”.

Based on these results, it was found that it is possible to obtain an array antenna having low dielectric loss and excellent reliability by forming liquid crystal alignment films using a liquid crystal aligning agent containing at least one of a compound having a specific partial structure (the compound [M]), a polymer having a vertically alignable group (the polymer [Q]), a crosslinking agent, and a polyimide. It is presumed that this is because the liquid crystal alignment film side is assisted by the compound having a specific partial structure, the polymer having a vertically alignable group, the crosslinking agent, or a polyimide so that change in dielectric constant is reduced, and thereby low dielectric loss and high reliability can be realized.

### Example 9

1. Formation of Liquid Crystal Alignment Film (High-Temperature Baking)

In the same manner as in Example 1, using a spinner, the liquid crystal aligning agent (A-1) was applied to each of surfaces of the patch substrate 12 and the slotted substrate 13 on which electrodes were to be formed. Next, the substrates to which the liquid crystal aligning agent (A-1) were applied were pre-baked on a hot plate at 80° C. for 2 minutes to form a coating film. Next, these substrates were heated (post-baked) at 230° C. for 15 minutes in an oven of which the inside was replaced with nitrogen. Thereby, liquid crystal alignment films each having an average film thickness of 2 μm were formed on the respective substrates.

2. Evaluation of Dielectric Loss Tangent

In the same manner as in Example 1, a dielectric loss tangent (tan δ) was measured using a perturbation-type space resonator manufactured by KEYCOM Corporation under conditions of a temperature of 25° C. and a frequency of 30 GHz. As a result, a dielectric loss tangent of the array antenna of this example was 0.0009, which was evaluated as “favorable.”

3. Evaluation of Durability of Antennas (Evaluation of Reliability)

In the same manner as in Example 1, durability of the antenna was evaluated. As a result, a dielectric loss tangent of the array antenna was 0.0013, which was evaluated as “favorable.”

### Example 10

1. Formation of Liquid Crystal Alignment Film (Slit Coat)

The liquid crystal aligning agent (A-2) was applied by slit coat to surfaces of each of the patch substrate 12 and the slotted substrate 13 on which electrodes were to be formed and which were used in Example 1, and these applied substrates were pre-baked on a hot plate at 80° C. for 2 minutes to form a coating film.

2. Evaluation of Application Properties (Observation of Pinholes with Optical Microscope)

The coating film obtained as above was observed under a microscope at a magnification of 100 times and 10 times to examine unevenness in film thickness and the presence or absence of pinholes. In particular, observation was performed to check whether pinholes were near steps of the substrates. Application properties were evaluated as “favorable” in a case where both unevenness in film thickness and pinholes were not observed even in observation with a microscope at a magnification of 100 times. Application properties were evaluated as “acceptable” in a case where at least one of unevenness in film thickness or pinholes was observed with a microscope at a magnification of 100 times, but both unevenness in film thickness and pinholes were not observed with a microscope at a magnification of 10 times. Application properties were evaluated as “unacceptable” in a case where at least one of unevenness in film thickness or pinholes was clearly observed with a microscope at a magnification of 10 times. In the present example, both unevenness in film thickness and pinholes were not observed even with a microscope at a magnification of 100 times, and therefore application properties were “favorable.”

In addition, the same evaluation of application properties was performed on the substrates, which were produced in Examples 2 and 4, each having a liquid crystal alignment film. The results were evaluated as “acceptable” in Example 2, and were evaluated as “acceptable” in Example 4. Based on these results, it can be said that slit coat is suitable for applying an aligning agent.

3. Evaluation of Dielectric Loss Tangent

An array antenna was produced in the same manner as in Example 1 using the substrate having the liquid crystal alignment film formed by slit coat. Next, in the same manner as in Example 1, a dielectric loss tangent (tan δ) was measured using a perturbation-type space resonator manufactured by KEYCOM Corporation under conditions of a temperature of 25° C. and a frequency of 30 GHz. As a result, a dielectric loss tangent of the array antenna of this example was 0.0009, which was evaluated as “favorable.”

4. Evaluation of Durability of Antennas (Evaluation of Reliability)

In the same manner as in Example 1, durability of the antenna was evaluated. As a result, a dielectric loss tangent of the array antenna was 0.0011, which was evaluated as “favorable.”

1. An array antenna that has a plurality of antenna units, the array antenna comprising:
a first substrate including a first dielectric substrate, a plurality of patch electrodes formed on the first dielectric substrate, and a plurality of thin-film transistors formed on the first dielectric substrate;
a second substrate including a second dielectric substrate disposed to face a surface of the first substrate on which the patch electrodes are formed, and a slot electrode formed on a surface of the second dielectric substrate facing the patch electrodes;
a liquid crystal layer disposed between the first substrate and the second substrate; and
a liquid crystal alignment film formed on a side of at least one of the first substrate and the second substrate and the side is near the liquid crystal layer,
wherein the liquid crystal alignment film is formed using a polymer composition that contains a compound [M] having at least one selected from the group consisting of a partial structure represented by Formula (1) and a nitrogen-containing heterocyclic ring; 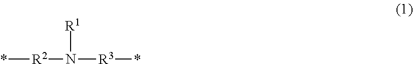
(in Formula (1), R¹ is a hydrogen atom or a monovalent organic group having 1 to 10 carbon atoms; R² and R³ are each independently a divalent organic group, where not both R² and R³ are aromatic ring groups; and “*” represents a bond).

2. The array antenna according to claim 1,
wherein the compound [M] has a partial structure represented by Formula (1-1) as the partial structure represented by Formula (1); 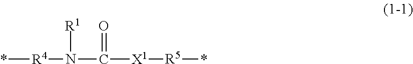
(in Formula (1-1), R¹ is a hydrogen atom or a monovalent organic group having 1 to 10 carbon atoms; X¹ is a single bond, an oxygen atom, or —NR⁶— (where R⁶ is a hydrogen atom or a monovalent organic group having 1 to 10 carbon atoms); R⁴ and R⁵ are each independently a divalent saturated hydrocarbon group; and “*” represents a bond).

3. The array antenna according to claim 1, wherein the nitrogen-containing heterocyclic ring is at least one selected from the group consisting of piperidine, piperazine, hexamethyleneimine, azole, pyridine, azepine, pyrrole, imidazole, pyrazole, oxazole, thiazole, imidazoline, pyrazine, pyrimidine, pyridazine, morpholine, thiazine, indole, isoindole, benzimidazole, purine, quinoline, isoquinoline, quinoxaline, cinnoline, pteridine, acridine, carbazole, and benzo-C-cinnoline.

4. The array antenna according to claim 1, wherein the compound [M] is at least one polymer selected from the group consisting of a polyamic acid, a polyimide, and a polyamic acid ester.

5. The array antenna according to claim 1, wherein the polymer composition contains a polymer having a photo-alignable group as the compound [M] or as a component different from the compound [M].

6. The array antenna according to claim 1, wherein the polymer composition further contains a compound having a crosslinkable group.

7. The array antenna according to claim 1, wherein a housing of the array antenna is formed using at least one polymer selected from the group consisting of an epoxy resin, a polyimide resin, a liquid crystal polymer, and a fluorine resin.

8. The array antenna according to claim 1, wherein the polymer composition contains a polymer having at least one partial structure selected from the group consisting of (V1) to (V5) in a side chain, as the compound [M] or as a component different from the compound [M]:
(V1) alkyl groups having 8 to 22 carbon atoms;
(V2) fluorine-containing alkyl groups having 6 to 18 carbon atoms;
(V3) monovalent groups in which any one of a benzene ring, a cyclohexane ring, and a heterocyclic ring is bonded to an alkyl group or fluorine-containing alkyl group having 1 to 20 carbon atoms;
(V4) monovalent groups which have a total of two or more rings of at least one kind selected from the group consisting of a benzene ring, a cyclohexane ring, and a heterocyclic ring, and in which the plurality of rings are bonded directly or via a divalent linking group; and
(V5) monovalent groups having a steroid skeleton and having 17 to 51 carbon atoms.

9. The array antenna according to claim 1, wherein the polymer composition contains a polyimide as the compound [M] or as a component different from the compound [M].

10. An array antenna having a plurality of antenna units, the array antenna comprising:
a first substrate including a first dielectric substrate, a plurality of patch electrodes formed on the first dielectric substrate, and a plurality of thin-film transistors formed on the first dielectric substrate;
a second substrate including a second dielectric substrate disposed to face a surface of the first substrate on which the patch electrodes are formed, and a slot electrode formed on a surface of the second dielectric substrate facing the patch electrodes;
a liquid crystal layer disposed between the first substrate and the second substrate; and
a liquid crystal alignment film formed on a side of at least one of the first substrate and the second substrate and the side is near the liquid crystal layer,
wherein the liquid crystal alignment film is formed using a polymer composition that contains a polymer having at least one partial structure selected from the group consisting of (V1) to (V5) in a side chain:
(V1) alkyl groups having 8 to 22 carbon atoms;
(V2) fluorine-containing alkyl groups having 6 to 18 carbon atoms;
(V3) monovalent groups in which any one of a benzene ring, a cyclohexane ring, and a heterocyclic ring is bonded to an alkyl group or fluorine-containing alkyl group having 1 to 20 carbon atoms;
(V4) monovalent groups which have a total of two or more rings of at least one kind selected from the group consisting of a benzene ring, a cyclohexane ring, and a heterocyclic ring, and in which the plurality of rings are bonded directly or via a divalent linking group; and
(V5) monovalent groups having a steroid skeleton and having 17 to 51 carbon atoms.

11. An array antenna having a plurality of antenna units, the array antenna comprising:
a first substrate including a first dielectric substrate, a plurality of patch electrodes formed on the first dielectric substrate, and a plurality of thin-film transistors formed on the first dielectric substrate;
a second substrate including a second dielectric substrate disposed to face a surface of the first substrate on which the patch electrodes are formed, and a slot electrode formed on a surface of the second dielectric substrate facing the patch electrodes;
a liquid crystal layer disposed between the first substrate and the second substrate; and
a liquid crystal alignment film formed on a side of at least one of the first substrate and the second substrate and the side is near the liquid crystal layer,
wherein the liquid crystal alignment film is formed using a polymer composition containing a compound having a crosslinkable group.

12. An array antenna having a plurality of antenna units, the array antenna comprising:
a first substrate including a first dielectric substrate, a plurality of patch electrodes formed on the first dielectric substrate, and a plurality of thin-film transistors formed on the first dielectric substrate;
a second substrate including a second dielectric substrate disposed to face a surface of the first substrate on which the patch electrodes are formed, and a slot electrode formed on a surface of the second dielectric substrate facing the patch electrodes;
a liquid crystal layer disposed between the first substrate and the second substrate; and
a liquid crystal alignment film formed on a side of at least one of the first substrate and the second substrate and the side is near the liquid crystal layer,
wherein the liquid crystal alignment film is formed using a polymer composition containing a polyimide.

13. A liquid crystal aligning agent for an array antenna having a plurality of antenna units,
wherein the array antenna includes:
a first substrate including a first dielectric substrate, a plurality of patch electrodes formed on the first dielectric substrate, and a plurality of thin-film transistors formed on the first dielectric substrate;
a second substrate including a second dielectric substrate disposed to face a surface of the first substrate on which the patch electrodes are formed, and a slot electrode formed on a surface of the second dielectric substrate facing the patch electrodes;
a liquid crystal layer disposed between the first substrate and the second substrate; and
a liquid crystal alignment film formed on a side of at least one of the first substrate and the second substrate and the side is near the liquid crystal layer,
wherein the liquid crystal aligning agent for an array antenna comprises:
a compound [M] having at least one selected from the group consisting of a partial structure represented by Formula (1) and a nitrogen-containing heterocyclic ring; 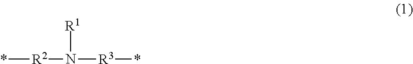
(in Formula (1), R¹ is a hydrogen atom or a monovalent organic group having 1 to 10 carbon atoms; R² and R³ are each independently a divalent organic group, where not both R² and R³ are aromatic ring groups; and “*” represents a bond).

14. A method for producing an array antenna having a plurality of antenna units,
wherein the array antenna includes:
a first substrate including a first dielectric substrate, a plurality of patch electrodes formed on the first dielectric substrate, and a plurality of thin-film transistors formed on the first dielectric substrate; and
a second substrate including a second dielectric substrate disposed to face a surface of the first substrate on which the patch electrodes are formed, and a slot electrode formed on a surface of the second dielectric substrate facing the patch electrodes,
wherein the method comprises:
a step of applying the liquid crystal aligning agent for an array antenna according to claim 13 to at least one surface of the first substrate and the second substrate on which electrodes are formed to form a liquid crystal alignment film; and
a step of allowing the first substrate and the second substrate to be disposed to face each other with a liquid crystal layer therebetween after forming the liquid crystal alignment film.

15. The method for producing an array antenna according to claim 14, heating the applied liquid crystal aligning agent for an array antenna at 160° C. or lower to form the liquid crystal alignment film.

16. The method for producing an array antenna according to claim 14, forming the liquid crystal alignment film by a photo alignment method.

17. The method for producing an array antenna according to claim 14, applying the liquid crystal aligning agent for an array antenna to the surface on which electrodes are formed by a slit coat method.
